(19) United States
(12) Patent Application Publication
(10) Pub. No.: US 2026/0045447 A1
(43) Pub. Date: Feb. 12, 2026

(54) BALANCING PROCESS KIT AREA TO WAFER AREA WITHIN A PROCESSING CHAMBER

(71) Applicant: Applied Materials, Inc., Santa Clara, CA (US)

(72) Inventors: Alvaro GARCIA, Mountain View, CA (US); Shreeram Jyoti DASH, San Jose, CA (US); Andreas SCHMID, Meyriez (CH); A N M Wasekul AZAD, Santa Clara, CA (US); Yue GUO, Redwood City, CA (US); Yang YANG, San Diego, CA (US); Kartik RAMASWAMY, San Jose, CA (US); Nicolas J. BRIGHT, Arlington, WA (US)

(21) Appl. No.: 19/252,963

(22) Filed: Jun. 27, 2025

Related U.S. Application Data
(63) Continuation-in-part of application No. 18/801,142, filed on Aug. 12, 2024, now abandoned.

(51) Int. Cl. H01J 37/32

(52) U.S. Cl. CPC H01J 37/32091; H01J 37/32715; H01J 2237/3321; H01J 2237/334

(57) ABSTRACT

Aspects generally relate to methods and systems for modulating capacitance values of different components within a processing chamber. The processing chamber includes an electrode driven by a power source coupled to a substrate, where a first capacitance is produced between the electrode and the substrate, an edge ring disposed adjacent the substrate, the edge ring having a second capacitance, and at least one capacitor disposed within the processing chamber to match the second capacitance of the edge ring to the first capacitance between the electrode and the substrate. In one example, the at least one capacitor is a fixed capacitor. In another example, the at least one capacitor is a variable capacitor. Components of the processing chamber may be powered by either a radiofrequency source or a pulse generator.

### CROSS-REFERENCE TO RELATED APPLICATIONS

This application is a continuation-in-part of U.S. patent application Ser. No. 18/801,142 filed Aug. 12, 2024, the contents of which are herein incorporated by reference.

### BACKGROUND

### Field

Aspects generally relate to methods and systems for balancing process kit area to wafer area within a processing chamber.

### Description of the Related Art

Plasma chambers are used in integrated circuit manufacturing to remove contaminants from the surface of a substrate and/or to etch surfaces of a substrate. To perform a plasma cleaning or etching process, an integrated circuit is placed in a plasma chamber and a pump removes most of the air from the chamber. A gas, such as argon, can then be injected into the chamber. Electromagnetic energy (e.g., radio frequency) is applied to the injected gas to excite the gas into a plasma state. The plasma releases ions that bombard the surface of the substrate to remove contaminants and/or material from the substrate. Atoms or molecules of the contaminants and/or substrate material are etched from the substrate and are, for the most part, pumped out of the chamber.

Some plasma process chambers are designed with liners having walls that form a tortuous flow path for gasses passing through the chamber. The parts of the plasma process chamber that form the liners are referred to as a process kit. The walls of the liners trap the plasma in the chamber while providing a path for the displaced contaminants and/or substrate materials to escape. However, when applying radiofrequency (RF) power or pulsed voltage technology (PVT), ring walking and electrical arcing issues may be present.

Therefore, there is a need for improved methods and systems for balancing process kit area to wafer area within a processing chamber to mitigate or prevent ring walking and electrical arcing issues.

### SUMMARY

Aspects generally relate to methods and systems for facilitating capacitance rebalancing within a processing chamber to mitigate or prevent ring walking and electrical arcing issues.

In one implementation, a processing chamber includes an electrode driven by a power source coupled to a substrate, where a first capacitance is produced between the electrode and the substrate, an edge ring disposed adjacent the substrate, the edge ring having a second capacitance, and at least one balance capacitor disposed within the processing chamber to match the second capacitance of the edge ring to the first capacitance between the electrode and the substrate.

In one implementation, a processing chamber includes an electrode driven by a power source coupled to a substrate, where a first capacitance is produced between the electrode and the substrate, an edge ring disposed adjacent the substrate, the edge ring having a second capacitance, and at least one variable balancing capacitor disposed within a junction box to match the second capacitance of the edge ring to the first capacitance between the electrode and the substrate.

In one implementation, a processing chamber includes an electrode driven by a power source coupled to a substrate, where a first capacitance is produced between the electrode and the substrate, an edge ring disposed adjacent the substrate, the edge ring having a second capacitance, at least one capacitor in series with the edge ring to match the second capacitance of the edge ring to the first capacitance between the electrode and the substrate, and a sliding ring disposed adjacent the edge ring to adjust capacitive coupling characteristics resulting from the at least one capacitor.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1 illustrates a processing chamber with a process kit, according to one implementation.

FIG. 2 illustrates a simplified capacitor model of a processing chamber where radiofrequency (RF) power is applied, according to one implementation.

FIG. 3 illustrates a simplified capacitor model of a processing chamber where pulsed voltage technology (PVT) is used, according to one implementation.

FIG. 4 illustrates a simplified capacitor model of a processing chamber where RF power is applied after capacitive balancing, according to one implementation.

FIG. 5 illustrates a simplified capacitor model of a processing chamber where PVT is used after capacitive balancing, according to one implementation.

FIG. 6 illustrates a simplified circuit showing capacitances of components within a processing chamber, according to one implementation.

FIGS. 7A-7B illustrate sliding ring or edge ring configurations, according to one implementation.

FIG. 8 illustrates how arcing affects movement of the edge ring, according to one implementation.

FIGS. 9A-9F illustrate different capacitance configurations where the capacitors have fixed values, according to one implementation.

FIG. 10 illustrates a circuit configuration for balancing capacitance values within a processing chamber, according to one implementation.

FIG. 11 illustrates movement of an edge ring when balancing capacitance values within a processing chamber, according to one implementation.

FIG. 12 illustrates a variable capacitance configuration for balancing capacitance values within a processing chamber, according to one implementation.

FIG. 13 illustrates a circuit configuration with a single variable capacitor, according to one implementation.

FIG. 14 illustrates a circuit configuration with two variable capacitors, according to one implementation.

FIG. 15 illustrates a circuit configuration with one variable capacitor and one energy source, according to one implementation.

FIG. 16 is an alternative circuit configuration shown in FIG. 13 with a single variable capacitor, according to another implementation.

FIG. 17 is an alternative circuit configuration shown in FIG. 14 with two variable capacitors, according to another implementation.

FIG. 18 is an alternative circuit configuration shown in FIG. 15 with one variable capacitor and one energy source, according to another implementation.

FIG. 19 is a circuit for balancing the process kit area to match the wafer area where PVT is used, according to another implementation.

FIG. 20 is a circuit for balancing the process kit area to match the wafer area where RF power is used, according to another implementation.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Aspects generally relate to methods and systems for optimizing capacitance values of different components within a processing chamber to mitigate or prevent ring walking and electrical arcing issues.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor substrates. Substrates may be exposed to a pretreatment process to polish, etch, reduce, oxidize, hydroxylate, anneal and/or bake the substrate surface. In addition to film processing directly on the surface of the substrate, any of the film processing steps disclosed may also be performed on an under-layer formed on the substrate as disclosed in more detail below, and the term “substrate surface” is intended to include such under-layer as the context indicates. Thus for example, where a film/layer or partial film/layer has been deposited onto a substrate surface, the exposed surface of the newly deposited film/layer becomes the substrate surface.

A substrate processing system typically refers to equipment used in semiconductor manufacturing to process substrates through various steps of fabrication, such as deposition, etching, and doping, to create integrated circuits. The substrate support with an edge ring is a component within this system, designed to hold and support the substrate (wafer) during processing. The substrate support is the main platform or chuck that holds the substrate firmly in place during processing. The substrate support provides mechanical support to prevent the substrate from moving or vibrating excessively, which may lead to defects in the processed layers. The edge ring is a ring-shaped structure that surrounds the perimeter of the substrate support. The purpose of the edge ring is to provide additional support and stabilization to the substrate, particularly around the edges. The edge ring helps to minimize edge effects during processing, such as non-uniformity in film deposition or etching, which can occur due to variations in gas flow or plasma distribution near the substrate edges. The edge ring also serves to seal the gap between the substrate and the chamber walls, preventing process gases or plasma from leaking out and ensuring uniform processing across the entire substrate surface.

One issue that may be present in processing chambers is “ring walking.” “Ring walking” typically refers to a phenomenon where a ring-shaped pattern of material deposition or erosion forms on the inner walls of the process chamber. This pattern can develop due to various factors such as uneven gas flow, temperature gradients, or localized variations in the plasma density. Ring walking may cause uniformity issues, process instability, and chamber contamination. The deposition or erosion pattern can lead to non-uniform processing of substrates placed within the chamber. This can result in variations in film thickness or material properties across the substrate surface. In other cases, ring walking may lead to process instability, causing fluctuations in plasma parameters or process performance. Material buildup on chamber walls can flake off and contaminate the processed substrates or interfere with the performance of sensitive components within the chamber.

Another issue that may be present in the processing chamber is electrical arcing or arcing. Arcing refers to the sudden discharge of electrical energy across the gap between two electrodes or between an electrode and the chamber walls. This discharge can disrupt the plasma process and potentially damage the chamber or the material being processed. To mitigate arcing in a plasma process chamber, several strategies may be employed, including process parameter optimization, improved electrode design, implementing gas purification systems, and using materials with high resistance to arcing.

Ring walking and arcing may be observed when using either radiofrequency (RF) power or pulse voltage technology (PVT). PVT is a technique used in various plasma processing applications, particularly in plasma etching and deposition. PVT involves applying voltage to the electrodes in a pulsed fashion rather than a continuous manner. This modulation of voltage can offer several advantages in controlling and optimizing the plasma process.

By pulsing the voltage applied to the electrodes, it is possible to control and adjust key plasma parameters such as ion energy, ion density, and electron temperature. This control allows for fine-tuning of the plasma characteristics to achieve desired process outcomes such as etch rate, selectivity, and sidewall profile in etching applications or film properties in deposition processes. Pulsing the voltage can help reduce the energy transferred to the substrate surface during plasma processing. This can minimize substrate damage, such as ion bombardment-induced damage or charging effects, particularly valuable for delicate or sensitive substrates. Pulsed voltage can be used to improve selectivity in plasma etching processes. By adjusting the pulse parameters, it is possible to selectively etch one material over another more precisely, leading to better control over device structures in semiconductor manufacturing, for example. Pulsed voltage can help mitigate plasma instabilities that may arise during continuous operation, leading to more stable and reproducible plasma processes. As such, PVT offers significant benefits in terms of process control, substrate damage reduction, and enhanced selectivity, making it a valuable technique in various plasma processing applications, particularly in advanced semiconductor manufacturing and nanotechnology.

Ring walking and arcing issues when using PVT can be traced to generation of different capacitances within the processing chamber. Different capacitances may lead to large instantaneous voltage differences between the substrate, process kit, and edge ring.

The example embodiments address such capacitance issues by adjusting capacitances within the processing chamber. In particular, the capacitance of the edge ring is modulated to match the capacitance of the substrate (i.e., the capacitance produced between the DC mesh of the electrostatic chuck (ESC) and the substrate). Modulating the capacitance of the edge ring relative to the capacitance of the substrate in, e.g., a chemical vapor deposition (CVD) processing chamber offers several benefits, particularly in enhancing the uniformity and quality of thin-film deposition or etching. The capacitance matching may result in improved film uniformity, enhanced process control, reduced particulate contamination, better step coverage, optimized deposition/etch rates, enhanced plasma stability, better energy efficiency, and greater flexibility in customizing different materials.

Three different approaches are presented to modulate the capacitance of the edge ring to match the capacitance of the substrate (i.e., the capacitance produced between the DC mesh of the electrostatic chuck (ESC) and the substrate). The first approach involves adjusting the capacitance based on a number of parameters, such as gaps and distance between components. The edge ring moves or is shifted when balancing the capacitance of the edge ring to the capacitance of the substrate. The second approach involves using fixed capacitors with set capacitance values. Similarly to the first approach, the edge ring moves or is shifted when balancing the capacitance of the edge ring to the capacitance of the substrate. The third approach involves using a variable capacitor. In contrast to the first and second approaches, the edge ring is fixed in place and does not move or shift during capacitance balancing. Further, in the first approach the edge ring includes a coating, whereas in the second and third approaches the edge ring does not include a coating. Each of the three different approaches enable capacitance rebalancing within the processing chamber. The capacitance rebalancing is performed to match the capacitance of the edge ring to the capacitance of the substrate (i.e., the capacitance produced between the DC mesh of the electrostatic chuck (ESC) and the substrate). The capacitance rebalancing within the processing chamber provides at least for a more uniform electric field distribution to achieve a more uniform deposition or etching process.

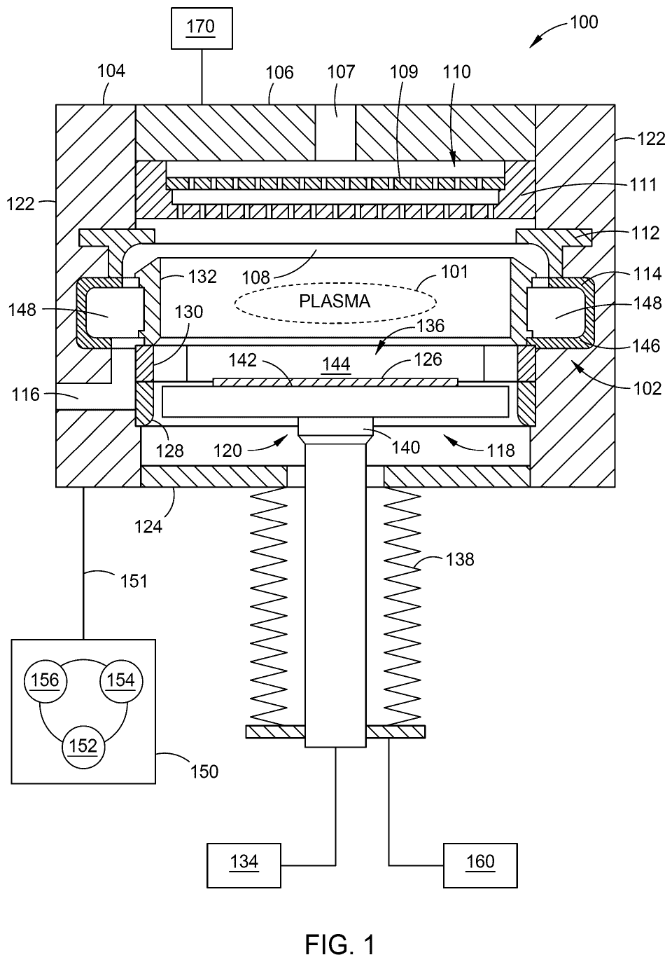

FIG. 1 schematically illustrates a processing chamber 100 having a process kit 102. The processing chamber 100 includes a chamber body 104 having chamber walls 122 and a bottom 124, and a lid 106 disposed on the chamber walls 122. The chamber walls 122, bottom 124, and lid 106 define an interior volume 108 of the processing chamber 100. The processing chamber 100 includes a gas distribution assembly 110 and a pedestal assembly 120. In one embodiment, the gas distribution assembly includes a gas inlet 107, a blocker plate 109, and a face plate or baseplate 111.

The pedestal assembly 120 is disposed in the interior volume and generally includes a substrate support 140. The substrate support 140 may be composed of aluminum or ceramic. The substrate support 140 may be an electrostatic chuck, a ceramic body, a heater, vacuum chuck, susceptor, or a combination thereof. The substrate support 140 has a substrate receiving surface 142 that receives and supports the substrate 126 during processing. The pedestal assembly 120 is coupled to the bottom 124 of the processing chamber 100 by a lift mechanism 134 that is configured to move the pedestal assembly 120 between a raised position (not shown) and lowered position 136. In the lowered position 136, lift pins (not shown) extend through the pedestal assembly 120 to space the substrate 126 from the pedestal assembly 120 to facilitate exchange of the substrate 126 with a substrate transfer mechanism (not shown) disposed exterior to the processing chamber 100, such as, for example, a robot. A bellows 138 is disposed between the pedestal assembly 120 and the bottom 124 of the chamber to isolate the interior volume 108 of the chamber body 104 from the interior of the pedestal assembly 120 and the exterior of the processing chamber 100.

The process kit 102 surrounds the pedestal assembly 120. The process kit 102 includes at least one or more of an isolator 112, a C-channel 114, and a liner assembly 118. The liner assembly 118 comprises a cylinder that serves to confine the energized process gas and to protect the chamber walls 122 of the processing chamber 100 from the energized process gas. The liner assembly 118 includes bottom liner 128, a middle liner 130, and a top liner 132. The bottom liner 128 rests on the bottom 124 of the chamber body 104. The middle liner 130 sits atop the bottom liner 128. The middle liner 130 further includes a slot 144 configured to allow a substrate 126 to pass through the middle liner 130 when being transferred into and out of the processing chamber 100. The top liner 132 sits atop the middle liner 130. The top liner 132, middle liner 130, and bottom liner 128 form a continuous surface bounding a portion of the interior volume 108 of the processing chamber 100.

The C-channel 114 includes an annular body 146 and a pumping region 148. The C-channel 114 is disposed within the chamber body 104 and surrounds both the liner assembly 118 and the pedestal assembly 120.

The isolator 112 is disposed in the interior volume 108 of the processing chamber 100. The isolator 112 surrounds the pedestal assembly 120 and the liner assembly 118. The isolator 112 extends above the liner assembly 118, and aids in directing the process gas across the substrate 126 and into the pumping region 148 defined in the annular body 146 of the C-channel 114. In one embodiment, such as that shown in FIG. 1, the isolator 112 has a t-shaped body.

After processing, both the process gas and the purge gas are exhausted from the interior volume 108 of the processing chamber 100. The isolator 112 directs the process gas and the purge gas downwards, towards the plurality of openings in the upper surface of the C-channel 114. Once the process gas and the purge gas enter the pumping region 148, the gases are flowed out of pumping region 148 through an exhaust port (not shown) defined in the bottom surface of the bottom annular portion. The gases then exit the chamber body 104 through a pumping port 116.

In the raised position, the lift mechanism 134 raises the substrate support 140 to a height, h, within the interior volume 108 of the processing chamber 100. The height may be, for example, such that there is about a 2 mm radial gap between the top liner 132 and the substrate support 140, and about a 5 mm gap between the isolator 112 and the substrate support 140. A substrate (not shown) is positioned on the substrate support 140 at a vertical height such that the slits line up along the side of the substrate. The bottom of the substrate lies below the top surface of the top liner to prevent any flow of the process gases below the pedestal assembly 120. During processing, the controller 150 communicates with the processing chamber 100 to flow a process gas from a process gas source 170 into the interior volume 108 of the processing chamber 100 for depositing a material on a substrate 126. The deposited material may be a dielectric material, such as a silicon based dielectric material. The gas distribution assembly 110 provides the process gas to the interior volume 108. The process gas may be, for example, TEOS. To aid in keeping the lower region of the processing chamber 100 clean, a purge gas may be flowed through the interior volume 108 of the processing chamber 100 from below the pedestal assembly 120. The purge gas is introduced by a separate gas line 160 through the bottom 124 of the processing chamber 100. The purge gas helps minimize undesirable deposition on the chamber walls 122 of the processing chamber 100 and the area of the processing chamber 100 below the pedestal assembly 120. The purge gas may be an inert gas, such as, for example, nitrogen, or argon.

The controller 150 is coupled to the processing chamber 100 and communicates with the motion mechanism via a communication cable 151 to raise or lower the pedestal assembly 120. The controller 150 is operable to control processing of the substrate 126 within the processing chamber 100. The controller 150 includes a programmable central processing unit (CPU) 152 that is operable with a memory 154 and a mass storage device, an input control unit, and a display unit (not shown), such as power supplies, clocks, cache, input/output (I/O) circuits, and the like, coupled to the various components of the processing chamber 100 to facilitate control of the processes of processing a substrate 126. The controller 150 may also include hardware for monitoring the processing of the substrate 126 through sensors (not shown) in the processing chamber 100.

To facilitate control of the processing chamber 100 and processing the substrate 126, the CPU 152 may be one of any form of general purpose computer processors for controlling the substrate process. The memory 154 is coupled to the CPU 152 and the memory 154 is non-transitory and may be one or more of readily available memory such as random access memory (RAM), read only memory (ROM), floppy disk drive, hard disk, or any other form of digital storage, local or remote. Support circuits 156 are coupled to the CPU 152 for supporting the CPU 152 in a conventional manner. The process for processing the substrate 126 is generally stored in the memory 154. The process for processing the substrate 126 may also be stored and/or executed by a second CPU (not shown) that is remotely located from the hardware being controlled by the CPU 152.

The memory 154 is in the form of computer-readable storage media that contains instructions, that when executed by the CPU 152, facilitates the operation of processing the substrate 126 in the processing chamber 100. The instructions in the memory 154 are in the form of a program product such as a program that implements the operation of processing the substrate 126. The program code may conform to any one of a number of different programming languages. In one example, the disclosure may be implemented as a program product stored in computer readable storage media for use with a computer system.

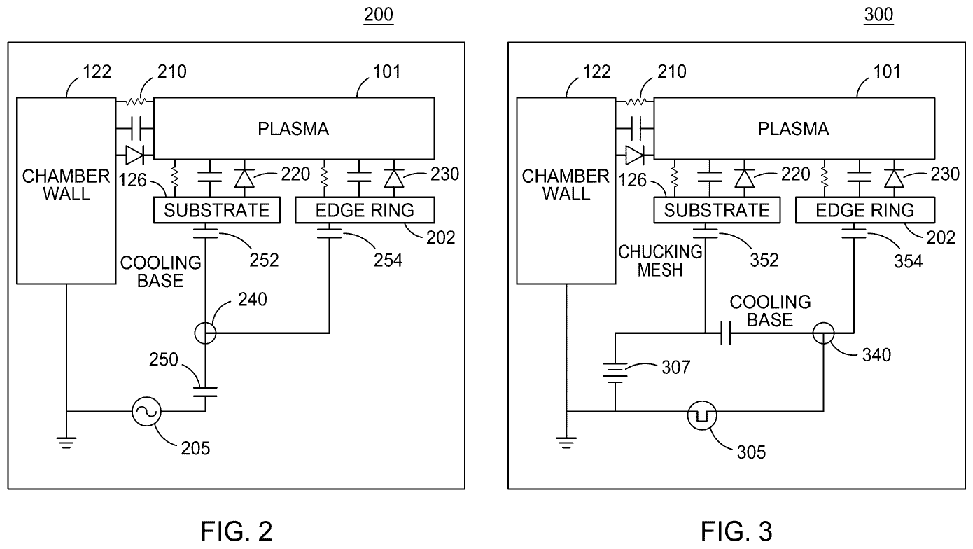

FIGS. 2-8 describe an embodiment for modulating the capacitance to an edge ring 202. The capacitance of the edge ring 202 is modulated to match the capacitance of the substrate 126. FIGS. 2-8 present a first approach where the capacitors are adjusted based on a number of parameters, such as gaps and distances between components. The edge ring 202 moves or is shifted when balancing the capacitance of the edge ring 202 to the capacitance of the substrate 126. The edge ring 202 also has a coating.

FIG. 2 illustrates a simplified capacitor model of a processing chamber where radiofrequency (RF) power is applied, according to one implementation.

In the simplified capacitor model 200, a plasma 101 is formed over the substrate 126 and the edge ring 202. A plasma sheath (see FIG. 11) is a thin layer of non-neutral plasma that forms at the interface between the plasma 101 and a solid surface, such as the substrate 126 and the edge ring 202. The plasma sheath is a region where there is a drop in potential from the plasma to the surface of the material. The potential drop leads to the formation of an electric field that accelerates ions toward the surface of the substrate 126 and the edge ring 202. The plasma 101 is formed within the chambers walls 122 of the processing chamber 100.

The objective is to match the capacitance 220 of the substrate 126 with the capacitance 230 of the edge ring 202. The plasma 101 is generated by applying a signal from, e.g., a RF generator 205. The RF generator 205 generates high-frequency electrical signals used to ionize the process gases to create the plasma 101. The RF generator can be in the range of, e.g., 13 MHz. The high-frequency signals are used to create an electric field within the processing chamber 100. When the process gases are introduced in the processing chamber 100, the electric field ionizes the gas molecules to create the plasma 101. The plasma 101 may include ions, electrons, and neutral particles and enhances the chemical reactions that lead to the deposition/etching of thin films on the substrate 126. A capacitance 210 may also be present between the plasma 101 and the chamber walls 122.

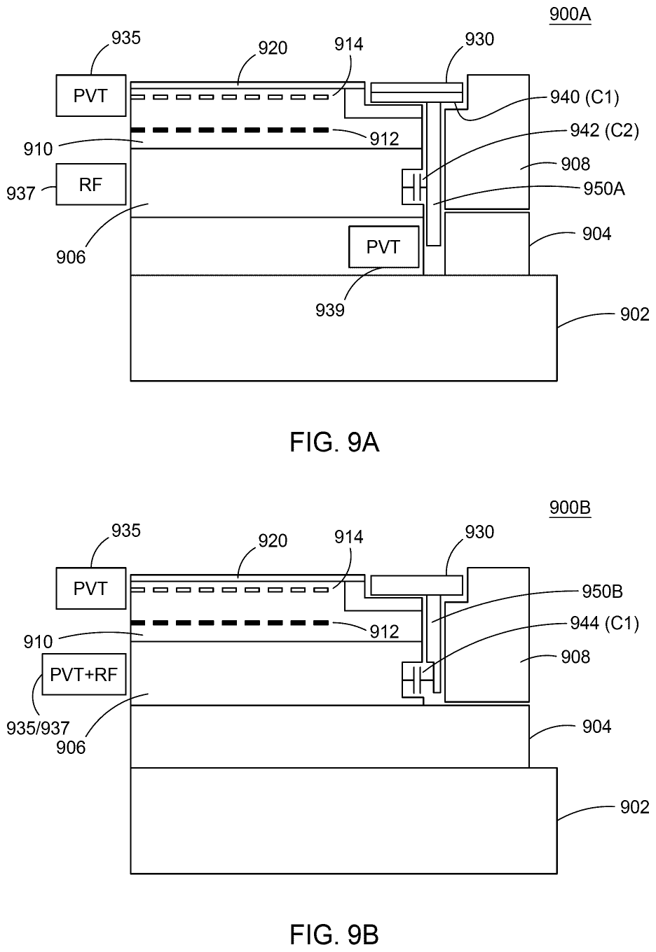

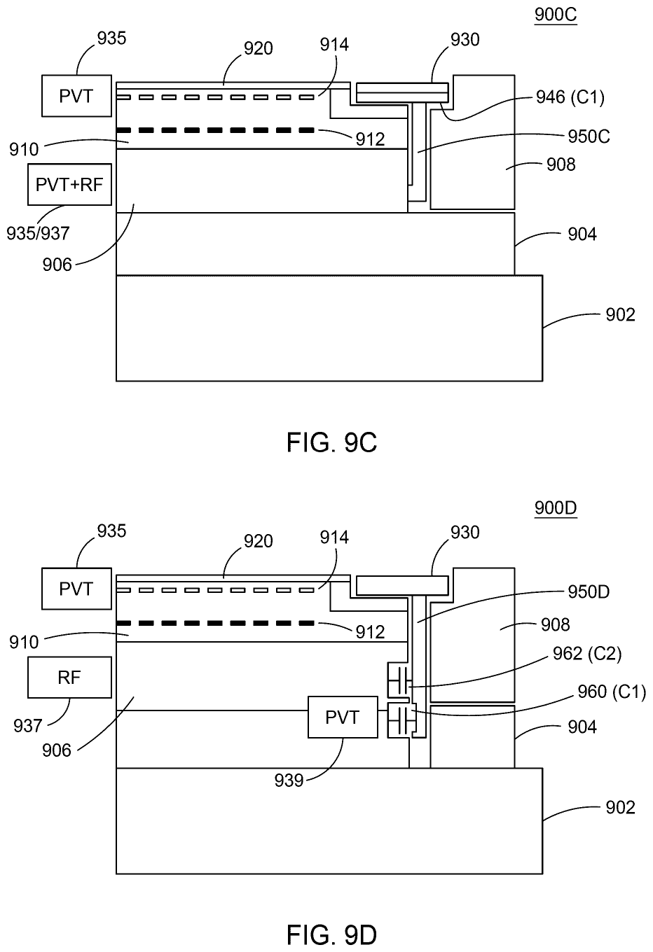

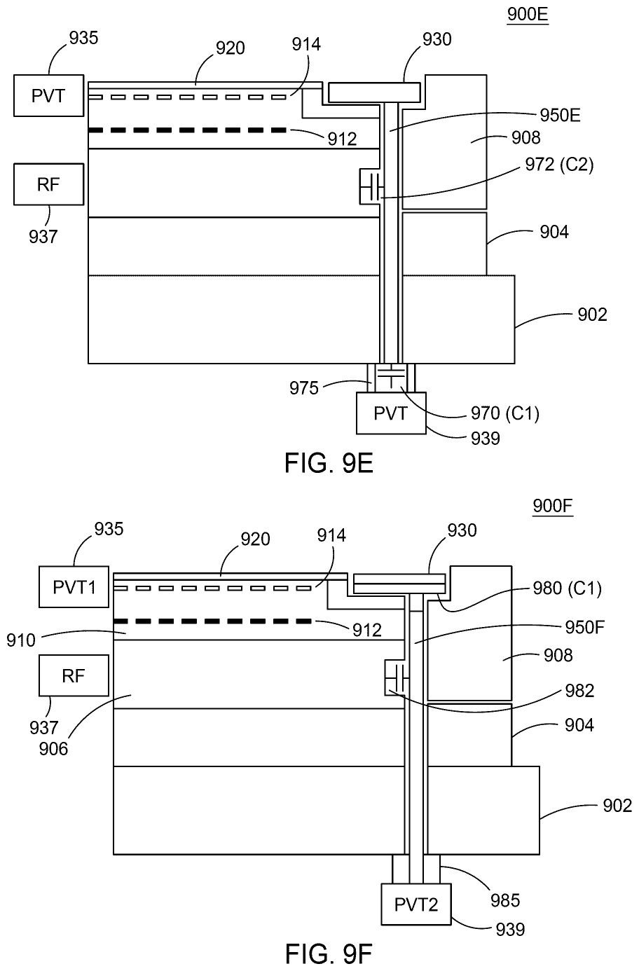

The processing chamber 100 includes several capacitances at various locations. A first capacitance 250 may be placed in series with the cathode 902 (FIGS. 9A-9F). A second capacitance 252 may be placed in series with the cooling plate 906 (FIGS. 9A-9F). A third capacitance 254 may be placed in series with the insulator material 908 positioned adjacent the edge ring 202. The point 240 may be referred to as a modulating point. The point 240 is in series with the first capacitance 250 and the second capacitance 252.

The point 240 may be a point between various capacitances that can be an adjustable junction where the capacitance can be varied to achieve desired electrical and plasma characteristics. The point 240 allows for matching the capacitance 220 of the substrate 126 to the capacitance 230 of the edge ring 202. Therefore, by adjusting the first capacitance 250, the second capacitance 252, and the third capacitance 254 to desired values, the capacitance 220 of the substrate 126 can be matched to the capacitance 230 of the edge ring 202. In other words, the first capacitance 250, the second capacitance 252, and the third capacitance 254 can be used to fine-tune the electrical properties of various components to achieve capacitance matching between the substrate 126 and the edge ring 202. The first capacitance 250, the second capacitance 252, and the third capacitance 254 are fixed capacitances. Therefore, fixed capacitances can be positioned at various locations within the processing chamber when RF power is applied to achieve a capacitance match between the capacitance of the substrate 126 and the edge ring 202.

FIG. 3 illustrates a simplified capacitor model of a processing chamber where pulsed voltage technology (PVT) is used, according to one implementation.

In the simplified capacitor model 300, a plasma 101 is formed over the substrate 126 and the edge ring 202. A plasma sheath (see FIG. 11) is formed at the interface between the plasma 101 and a solid surface, such as the substrate 126 and the edge ring 202. The plasma 101 is formed within the chambers walls 122 of the processing chamber 100. A capacitance 210 may also be present between the plasma 101 and the chamber walls 122.

The objective is to match the capacitance 220 of the substrate 126 with the capacitance 230 of the edge ring 202. The plasma 101 is generated by applying a signal from, e.g., a pulse generator 305 in cooperation with a battery 307. The pulse generator 305 applies a voltage in a series of short, high-intensity pulses rather than a continuous wave. This creates a pulsed plasma environment within the processing chamber 100, which can be controlled in terms of pulse duration, frequency, and amplitude. Pulsed plasmas can generate higher energy states and more reactive species compared to a continuous plasma. This may enhance the chemical reactions used for deposition or etching, potentially leading to better film quality and properties. In a pulsed plasma, the sheath dynamics are different from continuous plasmas. During the pulse on-time, a sheath forms rapidly, accelerating ions toward the substrate 126. During the off-time, the sheath collapses, thus reducing the ion bombardment. This cyclical formation and collapse of the plasma sheath can lead to more uniform ion energy distribution. The pulse generator 305 can be in the range of, e.g., 400 kHz. The plasma 101 may include ions, electrons, and neutral particles and enhances the chemical reactions that lead to the deposition or etching of thin films on the substrate 126.

The processing chamber 100 includes several capacitances at various locations. A first capacitance 350 may be placed in series with the cooling plate 906 (FIGS. 9A-9F). A second capacitance 352 may be placed in series with the DC mesh 914 of the ESC 910 (FIGS. 9A-9F). The DC mesh 914 is positioned above the AC heater electrodes 912. The DC mesh 914 can be referred to as an electrode. A third capacitance 354 may be placed in series with the insulator material 908 positioned adjacent the edge ring 202. The point 340 may be referred to as a modulating point. The point 340 is placed closer to the third capacitance 354 in series with the edge ring 202.

The point 340 may be a point between various capacitances that can be an adjustable junction where the capacitance can be varied to achieve desired electrical and plasma characteristics. The point 340 allows for matching the capacitance 220 of the substrate 126 to the capacitance 230 of the edge ring 202. Therefore, by adjusting the first capacitance 350, the second capacitance 352, and the third capacitance 354 to desired values, the capacitance 220 of the substrate 126 can be matched to the capacitance 230 of the edge ring 202. In other words, the first capacitance 350, the second capacitance 352, and the third capacitance 354 can be used to fine-tune the electrical properties of various components to achieve capacitance matching between the substrate 126 and the edge ring 202. The first capacitance 350, the second capacitance 352, and the third capacitance 354 are fixed capacitances. Therefore, fixed capacitances can be positioned at various locations within the processing chamber when pulses are applied to achieve a capacitance match between the capacitance of the substrate 126 and the edge ring 202.

Therefore, with respect to FIGS. 2 and 3, the modulating points may be positioned in different locations within the processing chamber 100 based on whether RF power or pulses are applied to generate the plasma 101. The values of the capacitors may be in the nanofarad (nF) range. The particular values of the capacitances may be optimized to create a substantially flat profile 1110 (FIG. 11) over the substrate 126 and the edge ring 202.

As a result, the objective is to achieve the substantially flat profile 1110 of FIG. 11 by matching the capacitance of the substrate 126 to the capacitance of the edge ring 202 whether PVT signals or RF signals are applied. As such, movement of the edge ring 202 should be taken into consideration when attempting to match the capacitances of the edge ring 202 and the substrate 126. The capacitance can be about 0.01 to 100 nanofarad (nF). Process engineers may fine-tune the capacitances in the processing chamber 100 to achieve the desired outcomes to enhance the quality and uniformity of the films deposited on substrates.

Additionally, the edge ring 202 is coated in the first approach. Coating of the edge ring 202 enhances process stability, improves film quality, and extends the lifetime of the equipment. The coating of the edge ring 202 protects against corrosion and wear, minimizes particle contamination, improves deposition uniformity, and enhances thermal stability. The coating may be applied using several different methods, including, but not limited to, physical vapor deposition (PVD), CVD, thermal spraying, anodization, electroplating, and using ceramic materials.

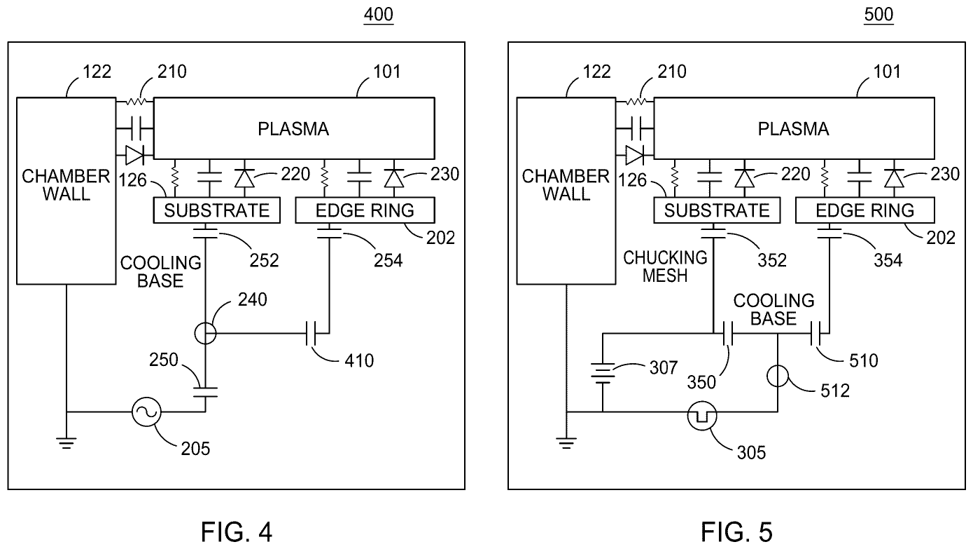

FIG. 4 illustrates a simplified capacitor model of a processing chamber where RF power is applied after capacitive balancing, according to one implementation.

In the simplified capacitor model 400, a plasma 101 is formed over the substrate 126 and the edge ring 202. A plasma sheath (see FIG. 11) is a thin layer of non-neutral plasma that forms at the interface between the plasma 101 and a solid surface, such as the substrate 126 and the edge ring 202. The plasma 101 is formed within the chambers walls 122 of the processing chamber 100. A capacitance 210 may also be present between the plasma 101 and the chamber walls 122.

The objective is to match the capacitance 220 of the substrate 126 with the capacitance 230 of the edge ring 202. The plasma 101 is generated by applying a signal from, e.g., a RF generator 205. The RF generator 205 generates high-frequency electrical signals used to ionize the process gases to create the plasma 101. The RF generator can be in the range of, e.g., 13 MHz. The high-frequency signals are used to create an electric field within the processing chamber 100. When the process gases are introduced in the processing chamber 100, the electric field ionizes the gas molecules to create the plasma 101. The plasma 101 may include ions, electrons, and neutral particles and enhances the chemical reactions that lead to the deposition or etching of thin films on the substrate 126.

The processing chamber 100 includes several capacitances at various locations. A first capacitance 250 may be placed in series with the cathode 902 (FIGS. 9A-9F). A second capacitance 252 may be placed in series with the cooling plate 906 (FIGS. 9A-9F). A third capacitance 254 may be placed in series with the insulator material 908 positioned adjacent the edge ring 202. Additionally, in contrast to FIG. 2, a fourth capacitance 410 may be placed in series with the third capacitance 254. The fourth capacitance 410 may be placed in series with the insulator 904 (FIGS. 9A-9F) positioned between the cathode 902 and the cooling plate 906. The point 240 may be referred to as a modulating point. The point 240 is in series with the first capacitance 250 and the second capacitance 252. The point 240 is also in series with the third capacitance 254 and the fourth capacitance 410.

The point 240 may be a point between various capacitances that can be an adjustable junction where the capacitance can be varied to achieve desired electrical and plasma characteristics. The point 240 allows for matching the capacitance 220 of the substrate 126 to the capacitance 230 of the edge ring 202. Therefore, by adjusting the first capacitance 250, the second capacitance 252, the third capacitance 254, and the fourth capacitance 410 to desired values, the capacitance 220 of the substrate 126 can be matched to the capacitance 230 of the edge ring 202. In other words, the first capacitance 250, the second capacitance 252, the third capacitance 254, and the fourth capacitance 410 can be used to fine-tune the electrical properties of various components to achieve capacitance matching between the substrate 126 and the edge ring 202. The first capacitance 250, the second capacitance 252, the third capacitance 254, and the fourth capacitance 410 are fixed capacitances. Therefore, fixed capacitances can be positioned at various locations within the processing chamber when RF power is applied to achieve a capacitance match between the capacitance of the substrate 126 and the edge ring 202.

FIG. 5 illustrates a simplified capacitor model of a processing chamber where pulsed voltage technology (PVT) is used after capacitive balancing, according to one implementation.

In the simplified capacitor model 500, a plasma 101 is formed over the substrate 126 and the edge ring 202. A plasma sheath (see FIG. 11) is formed at the interface between the plasma 101 and a solid surface, such as the substrate 126 and the edge ring 202. The plasma 101 is formed within the chambers walls 122 of the processing chamber 100. A capacitance 210 may also be present between the plasma 101 and the chamber walls 122.

The objective is to match the capacitance 220 of the substrate 126 with the capacitance 230 of the edge ring 202. The plasma 101 is generated by applying a signal from, e.g., a pulse generator 305 in cooperation with a battery 307. The pulse generator 305 applies a voltage in a series of short, high-intensity pulses rather than a continuous wave. This creates a pulsed plasma environment within the processing chamber 100, which can be controlled in terms of pulse duration, frequency, and amplitude. Pulsed plasmas can generate higher energy states and more reactive species compared to a continuous plasma. The pulse generator 305 can be in the range of, e.g., 400 kHz.

The processing chamber 100 includes several capacitances at various locations. A first capacitance 350 may be placed in series with the cooling plate 906 (FIGS. 9A-9F). A second capacitance 352 may be placed in series with the DC mesh 914 of the ESC 910 (FIGS. 9A-9F). A third capacitance 354 may be placed in series with the insulator material 908 positioned adjacent the edge ring 202. Additionally, in contrast to FIG. 3, a fourth capacitance 510 may be placed in series with the third capacitance 354. The fourth capacitance 510 may be placed in series with the insulator 904 (FIGS. 9A-9F) positioned between the cathode 902 and the cooling plate 906. The point 512 may be referred to as a modulating point. The point 512 is placed closer to the third capacitance 354 in series with the edge ring 202.

The point 512 may be a point between various capacitances that can be an adjustable junction where the capacitance can be varied to achieve desired electrical and plasma characteristics. The point 512 allows for matching the capacitance 220 of the substrate 126 to the capacitance 230 of the edge ring 202. Therefore, by adjusting the first capacitance 350, the second capacitance 352, the third capacitance 354, and the fourth capacitance 510 to desired values, the capacitance 220 of the substrate 126 can be matched to the capacitance 230 of the edge ring 202. In other words, the first capacitance 350, the second capacitance 352, the third capacitance 354, and the fourth capacitance 510 can be used to fine-tune the electrical properties of various components to achieve capacitance matching between the substrate 126 and the edge ring 202. The first capacitance 350, the second capacitance 352, the third capacitance 354, and the fourth capacitance 510 are fixed capacitances. Therefore, fixed capacitances can be positioned at various locations within the processing chamber when pulses are applied to achieve a capacitance match between the capacitance of the substrate 126 and the edge ring 202.

Therefore, with respect to FIGS. 4 and 5, the modulating points may be positioned in different locations within the processing chamber 100 based on whether RF power or pulses are applied to generate the plasma 101. The values of the capacitors may be in the nanofarad (nF) range. The particular values of the capacitances may be optimized to create a substantially flat profile 1110 (FIG. 11) over the substrate 126 and the edge ring 202.

As a result, the objective is to achieve the substantially flat profile 1110 by matching the capacitance of the substrate 126 to the capacitance of the edge ring 202 whether PVT signals or RF signals are applied. As such, movement of the edge ring 202 may be taken into consideration when attempting to match the capacitances of the edge ring 202 and the substrate 126. The capacitance can be about 0.01 to 100 nanofarad (nF). Process engineers may fine-tune the capacitances in the processing chamber 100 to achieve the desired outcomes to enhance the quality and uniformity of the films deposited on substrates.

Additionally, the edge ring 202 is coated in the first approach pertaining to FIGS. 2-5. Coating of the edge ring 202 enhances process stability, improves film quality, and extends the lifetime of the equipment. The coating of the edge ring 202 protects against corrosion and wear, minimizes particle contamination, improves deposition/etching uniformity, and enhances thermal stability. The coating does not affect the capacitance values or capacitances within the processing chamber 100.

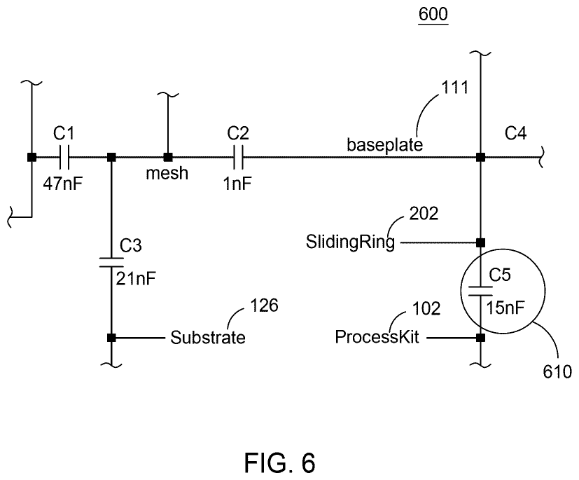

FIG. 6 illustrates a simplified circuit showing capacitances of components within a processing chamber, according to one implementation.

The simplified circuit 600 illustrates a capacitance C1 between the mesh and the chamber walls, a capacitance C2 between the mesh and the baseplate 111, a capacitance C3 between the mesh and the substrate 126, a capacitance C4 between the baseplate 111 and the chamber walls, and a capacitance C5 between the edge ring 202 and the process kit 102. The capacitance C5 is adjusted (area 610) to match the capacitance of the substrate 126 to the capacitance of the edge ring 202. In one example, the capacitance C5 may be reset to 15 nF (instead of e.g., 2.75 nF; area 610). Thus, the capacitance of the edge ring 202 may be adjusted in accordance with the capacitance of the process kit 102, which may result in a voltage reduction of about 85%. The voltage reduction is noticed when, e.g., a pulsed voltage is applied as in FIGS. 3 and 5. The advantages of reducing the applied pulsed voltage results in improved process control and uniformity, minimization of contaminants and defects, enhanced equipment longevity, energy efficiency (i.e., lower power consumption), improved safety (i.e., lower risk of electrical arcing and reduced thermal stress), better control of reactive species (i.e., optimized chemical reactions), and scalability and flexibility improvements. These benefits contribute to higher quality films, reduced operational costs, and more reliable and efficient processes.

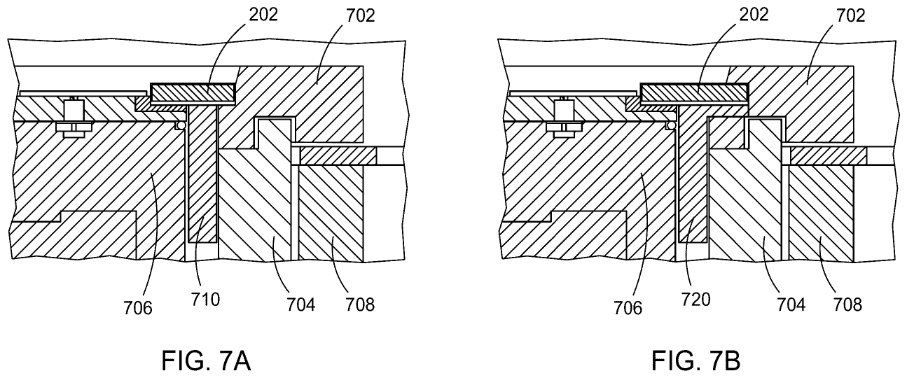

FIGS. 7A-7B illustrate sliding ring or edge ring configurations, according to one implementation.

In FIG. 7A, the edge ring 202 is secured adjacent an insulator 702. The insulator 702 is, e.g., a quartz insulator that is a separate piece, which is part of the process kit 102. The edge ring 202 rests on a sliding ring 710. The sliding ring 710 is a substantially rectangular segment. The sliding ring 710 is made of a conducting material and coated with a dielectric material. The sliding ring 710 may be constructed, e.g., from aluminum. The purpose of the sliding ring 710 is to provide capacitive coupling capabilities. Capacitive coupling in the processing chamber 100 involves transferring energy to the plasma 101 through sliding ring 710. The sliding ring 710 thus acts as an intermediary electrical connection that can move to adjust the coupling characteristics.

Further, the insulator 702 rests on a quartz pipe insulator 704, which serves to isolate from ground. The electrical ground is the outermost portion 708. The sliding ring 710 is positioned adjacent a cooling base 706. The cooling base 706 may be constructed from, e.g., aluminum. In RF embodiments, the cooling base 706 carries energy or power to the plasma 101. In PVT embodiments, the cooling base 706 carries the same pulsed voltage as is applied to the plasma 101 and the substrate 126.

FIG. 7B, the edge ring 202 is secured adjacent an insulator 702. The insulator 702 is, e.g., a quartz insulator that is a separate piece, which is part of the process kit 102. The edge ring 202 rests on a sliding ring 720. The sliding ring 720 is a substantially L-shaped segment in contrast to the embodiment of FIG. 7A. A portion of the sliding ring 720 extends under the edge ring 202 such that a side surface of the sliding ring 720 directly contacts a side surface of the insulator 702. The thickness of the top portion of the sliding ring 720 may have a thickness equal to the thickness of the edge ring 202.

The sliding ring 720 is made of a conducting material and coated with a dielectric material. The sliding ring 720 may be constructed, e.g., from aluminum. The purpose of the sliding ring 720 is to provide capacitive coupling capabilities. Capacitive coupling in the processing chamber 100 involves transferring energy to the plasma 101 through sliding ring 720. The sliding ring 720 thus acts as an intermediary electrical connection that can move to adjust the coupling characteristics.

Similarly to FIG. 7A, the insulator 702 rests on a quartz pipe insulator 704, which serves to isolate from ground. The electrical ground is the outermost portion 708. The sliding ring 720 is positioned adjacent a cooling base 706. The cooling base 706 may be constructed from, e.g., aluminum. In RF embodiments, the cooling base 706 carries energy or power to the plasma 101. In PVT embodiments, the cooling base 706 carries the same pulsed voltage as is applied to the plasma 101 and the substrate 126.

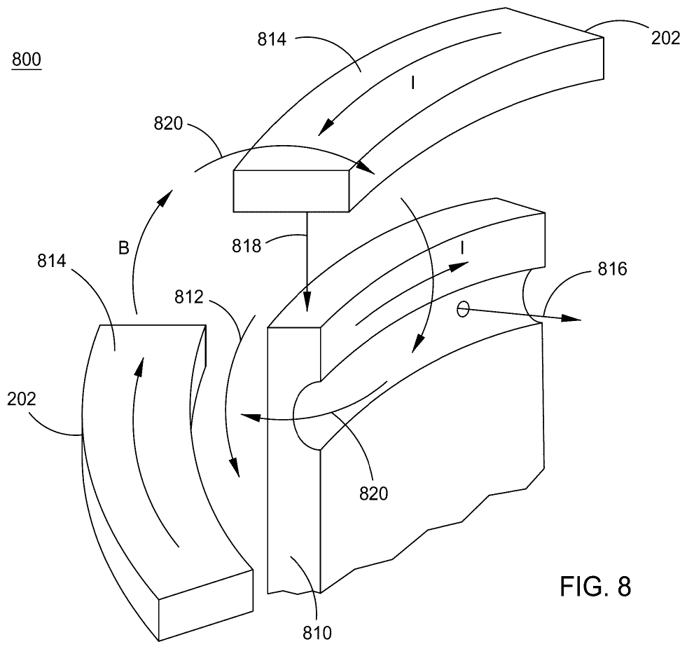

FIG. 8 illustrates how arcing affects movement of the edge ring, according to one implementation.

The diagram 800 provides an explanation of how ring walking can occur in case of electrical arcing. Ring walking refers to the movement or displacement of the edge ring 202, which can occur due to various factors including electrical arcing. Electrical arcing between the mesh of the ESC and the edge ring can lead to several phenomena that cause this movement. Electrical arcing is the discharge of electrical current across a gap between two conductive materials. Electrical arcing can be caused by high voltage differences, imperfections in the dielectric materials, contamination or damage to insulating surfaces.

Movement of the edge ring 202 can disrupt the uniformity of the electric field and plasma distribution, leading to non-uniform film deposition. Continuous movement and arcing of the edge ring 202 can increase wear and tear on the edge ring 202 and the ESC 910 (FIGS. 9A-9F). Uncontrolled movement of the edge ring 202 can introduce instability into the deposition or etching process, affecting repeatability and consistency of films.

Ring walking can be prevented by minimizing the arcing. The arcing can be minimized by inserting the sliding ring proposed above in FIGS. 7A-7B. A sliding ring 810 is shown positioned under the edge ring 202. A current 812 depict the electrical current from an arc event flowing to and from a connection point 816. The connection point 816 can be any “clock position” or azimuthal position, yet it will rarely be at the same clock position as the connection point 818 (also referred to as an arc point). A current 814 depict the current drawn from the process kit 102 to the connection point 818. The current 814 is received from both directions, as illustrated. Stated differently, the connection point 816 is between the sliding ring 810 and the cooling base 706 (FIGS. 7A-7B), and the connection point 818 is between the process kit 102 and the sliding ring 810. The current 812 generates a magnetic field (B) that crosses the process kit current (i.e., the current 814) leading to the Lorentz force or the “I cross B” force pushing on the process kit 102 in an upward direction (arrows 820). The same magnetic field causes a rotational force when it encounters the vertical current (i.e., the connection point 818) in the process kit 102. This electrical arcing forces movement of the edge ring 202, e.g., either in an upward or a downward direction. By positioning a sliding ring 810 adjacent the edge ring 202, the electrical arcing may be reduced and the movement of the edge ring 202 may be significantly reduced.

Advantages of reducing the movement of the edge ring 202 include, e.g., improved process stability, enhanced film quality, extended equipment longevity, operational efficiency, thermal stability, and reduced risk of mechanical failures. Improved process stability leads to consistent plasma conditions and uniform electric fields, enhanced film quality results in uniform deposition or etching and minimized edge effects, extended equipment longevity is a result of reduced wear and tear, and decreased contamination, operational efficiency results from simplified process control and lower maintenance costs, thermal stability results from consistent temperature and improved heat management, and reduced risk of mechanical failures results from enhanced reliability and simpler system design. Therefore, by minimizing the movement of the edge ring 202, processing systems can achieve more stable, efficient, and high-quality deposition/etching processes, ultimately leading to better performance and lower operational costs.

FIGS. 9A-11 describe an embodiment for modulating the capacitance to the edge ring. The capacitance of the edge ring 930 is modulated to match the capacitance of the substrate 920. FIGS. 9A-11 present a second approach where the capacitors are fixed. The fixed capacitors have a set capacitance value that cannot be adjusted after manufacturing. Similarly to the first approach presented above based on FIGS. 1-8, the edge ring 930 moves or is shifted when balancing the capacitance of the edge ring 930 to the capacitance of the substrate 920. The edge ring 930 does not include a coating in the second approach.

FIGS. 9A-9F illustrate different capacitance configurations where the capacitors have fixed values, according to one implementation.

FIG. 9A depicts a simplified capacitance configuration 900A between the substrate 920 and the edge ring 930 within the processing chamber 100 of FIG. 1.

An insulator 904 is formed over a cathode 902. The cathode 902 is part of the plasma generation system and serves as one of the electrodes where the plasma is generated. The cathode 902 works with the other components within the processing chamber 100 to generate and sustain the plasma. A cooling plate 906 is formed over the insulator 904. The cooling plate 906 is used to manage the temperature of the substrate 920. Thus, the cooling plate 906 provides for temperature control and thermal uniformity across the substrate 920. The electrostatic chuck (ESC) 910 is placed over the cooling plate 906. The ESC 910 includes a DC mesh 914 and AC heater electrodes 912. The ESC 910 is used to hold the substrate 920 in place during the process. The ESC 910 uses electrostatic forces to secure the substrate 920 firmly thereon. The ESC 910 is often integrated with the cooling plate 906 to provide efficient thermal management while securing the substrate 920 thereon. Therefore, the ESC 910 ensures substrate stability and thermal management, the cooling plate 906 maintains temperature control, and the cathode 902 enables plasma generation for different processes. The insulator 904 is placed between the cooling plate 906 and the cathode 902 to electrically isolate the two components.

An edge ring 930 is placed adjacent to the substrate 920. The functions of the edge ring 930 include improving film uniformity, protecting the chamber components, and managing heat distribution. The edge ring 930 helps minimize the non-uniform distribution near the edges of the substrate 920 to reduce or eliminate the edge effect in processes. The edge ring 930 also assists in managing the electric field distribution around the substrate 920 to ensure more uniform plasma density, which in turn provides for more uniform deposition or etching. The edge ring 930 also protects or shields the chamber walls and other chamber components from being coated with the deposition material. In one example the edge ring 930 is constructed from silicon carbide (SiC). The edge ring 930 is supported by an insulator material 908. The insulator material 908 rests between the edge ring 930 and the susceptor (not shown) to electrically isolate the edge ring 930 from the susceptor. The insulator material 908 also helps in maintaining thermal stability by reducing heat transfer between the edge ring 930 and the susceptor. The objective of this structure is to match the capacitance of the edge ring 930 to the capacitance of the substrate 920. The capacitance can be about 0.01 nF to 100 nF.

In FIG. 9A, a first capacitor 940 (C1) is coupled to the edge ring 930 and a second capacitor 942 (C2) is coupled to the cooling plate 906. A connector 950A extends from the first capacitor 940 of the edge ring 930 to the insulator 904. The connector 950A is a physical connector, such as a wire, that forms a connection between the first capacitor 940 and the second capacitor 942. The connector 950A may be referred to as a conductor line. The second capacitor 942 (C2) may be a lumped capacitor. A lumped capacitor is a simplified model in which all the capacitance of the system is assumed to be concentrated at a single point or component. It is assumed that the capacitor has its entire capacitance between two discrete points. Thus, a lumped capacitor is a discrete capacitor component on a circuit board.

A pulse voltage technology (PVT) signal 935 (or first PVT signal) is applied to the DC mesh 914. A radiofrequency (RF) signal 937 is applied to the cooling plate 906. PVT is a method used to control and manipulate electrical signals and power delivery through the use of short, high-intensity voltage pulses. The applied pulse can range from nanoseconds to milliseconds. The pulses can have high peak voltages. The pulses may also be repeated and the frequency at which the pulses are repeated can range from single pulses to high-frequency pulse trains. The PVT signal 935 is supplied by a first power supply and the RF signal 937 is supplied by a second power supply. Therefore, each power signal may have its own independent power supply. In another example, there may be two PVT power sources to provide for two PVT signals. In this case, a second PVT signal 939 may be applied to the connector 950A in series with the insulator 904.

The first capacitor 940 (C1) provides an equivalent capacitance the same as the capacitance between the DC mesh 914 and the substrate 920. The second capacitor 942 (C2) is equivalent to the capacitance between the DC mesh 914 and the cooling plate 906. Thus, the second PVT signal 939 is applied to the edge ring 930 and the first PVT signal 935 is applied to the DC mesh 914. The total capacitance for the RF signal 937 is the same for both the center and the edge. The center is from the cooling plate 906 to the DC mesh 914 and from the DC mesh 914 to the substrate 920.

The PVT signal 935 is measured at the center of the substrate 920 and is applied to the DC mesh 914, measuring the capacitance between the DC mesh 914 and the substrate 920. The RF signal 937 is applied to the cooling plate 906. By adding the first capacitor 940 (C1) and the second capacitor 942 (C2), the capacitance of the edge ring 930 may be matched to the capacitance of the substrate 920.

FIG. 9B depicts a simplified capacitance configuration 900B between the edge ring 930 and the cooling plate 906 within the processing chamber 100 of FIG. 1.

In FIG. 9B, a single capacitor 944 (C1) is coupled between the edge ring 930 and the cooling plate 906. A connector 950B extends from the single capacitor 944 (C1) of the edge ring 930 to the cooling plate 906. The connector 950B is a physical connector, such as a wire, that forms a connection between the edge ring 930 and the cooling plate 906. The connector 950B may be referred to as a conductor line. The single capacitor 944 (C1) may be a lumped capacitor.

A PVT signal 935 is applied to the DC mesh 914. A RF signal 937 or the PVT signal 935 may be applied to the cooling plate 906. Therefore, two frequencies share a common capacitor, that is, the single capacitor 944 (C1). The single capacitor 944 can target a lower frequency rather than a higher frequency because the higher frequency won't have as much of an impact to the capacitance match between the edge ring 930 and the substrate 920.

The simplified capacitance configuration 900B of FIG. 9B may not provide as good a match between the capacitance of the edge ring 930 and the capacitance of the substrate 920 as the simplified capacitance configuration 900A of FIG. 9A. However, the simplified capacitance configuration 900B may be a more cost-effective solution than the simplified capacitance configuration 900A. Thus, there is a trade-off between cost and achieving the more precise capacitance match between the edge ring 930 and the substrate 920. The capacitance can be about 0.01 to 100 nanofarad (nF).

FIG. 9C depicts a simplified capacitance configuration 900C between the edge ring 930 and the substrate 920 within the processing chamber 100 of FIG. 1.

In FIG. 9C, a single capacitor 946 (C1) is coupled between the edge ring 930 and the substrate 920. A connector 950C extends from the single capacitor 946 (C1) of the edge ring 930 to the cooling plate 906. The connector 950C is a physical connector, such as a wire, that forms a connection between the edge ring 930 and the cooling plate 906. The connector 950C may be referred to as a conductor line.

A PVT signal 935 is applied to the edge ring 930. A RF signal 937 or the PVT signal 935 may be applied to the cooling plate 906. Therefore, two frequencies share a common capacitor, that is, the single capacitor 946 (C1). The single capacitor 946 can target a lower frequency rather than a higher frequency because the higher frequency won't have as much of an impact to the capacitance match between the edge ring 930 and the substrate 920.

The simplified capacitance configuration 900C of FIG. 9C may not provide as good a match between the capacitance of the edge ring 930 and the capacitance of the substrate 920 as the simplified capacitance configuration 900A of FIG. 9A. However, the simplified capacitance configuration 900C may be a more cost-effective solution than the simplified capacitance configuration 900A. Thus, there is a trade-off between cost and achieving the more precise capacitance match between the edge ring 930 and the substrate 920.

The difference between the simplified capacitance configuration 900C of FIG. 9C and the simplified capacitance configuration 900B of FIG. 9B is the placement of the single capacitor. In FIG. 9B, the single capacitor 944 (C1) is placed in series with the cooling plate 906, whereas in FIG. 9C, the single capacitor 946 (C1) is placed in series with the edge ring 930.

In the processing chamber 100, the placement of capacitors can significantly impact the performance and stability of the deposition or etching process, as well as play a role in matching the capacitance between the edge ring 930 and the substrate 920. The placement of the capacitor closer to the edge ring 930 or the cooling plate 906 can affect the system in different ways due to their roles in temperature control, electrical properties, and process stability.

Placing the capacitor closer to the edge ring 930 can help in stabilizing the electrical potential near the edge of the substrate 920. This ensures uniform electric fields and minimizing edge effects. Placing the capacitor closer to the edge ring 930 can further help in maintaining a more uninform electric field across the substrate 920. A uniform electric field is valuable for consistent film thickness and properties across the entire surface of the substrate 920.

Placing the capacitor closer to the cooling plate 906 can help in managing the thermal aspects of the deposition/etching process more effectively. The cooling plate 906 is integral in maintaining the substrate 920 at a desired temperature, and a capacitor in this location can support the thermal management system. Placing the capacitor closer to the cooling plate 906 can further enhance thermal stability near the cooling plate to ensure a more consistent temperature across the substrate 920. A capacitor near the cooling plate 906 may also help in dissipating heat more effectively, especially if the capacitor is part of a power supply circuit that generates heat. Moreover, placement of a capacitor closer to the cooling plate 906 can provide for better electrical isolation from the deposition/etching area, thus reducing potential interference with the deposition/etching process.

Therefore, the specific needs of the deposition/etching process may dictate the best placement of capacitors. Balancing thermal management and electrical stability may be considered in achieving desired capacitance matches between the edge ring 930 and the substrate 920. The capacitance can be about 0.01 to 100 nanofarad (nF).

FIG. 9D depicts a simplified capacitance configuration 900D between the substrate 920 and the edge ring 930 within the processing chamber 100 of FIG. 1.

In FIG. 9D, a first capacitor 960 (C1) is coupled to the insulator 904 and a second capacitor 962 (C2) is coupled to the cooling plate 906. A connector 950D extends from the edge ring 930 to the insulator 904. The connector 950D may be a physical connector, such as a wire, that forms a connection between the first capacitor 960 and the second capacitor 962. The connector 950D may be referred to as a conductor line. In some cases, the connector 950D can also be a transmission line, which may contribute to the total equivalent capacitance from the first capacitor 960 (C1) and the second capacitor (C2) to the edge ring 930. The first capacitor 960 (C1) and the second capacitor 962 (C2) may be lumped capacitors.

A pulse voltage technology (PVT) signal 935 is applied to the DC mesh 914 and a PVT signal 939 is applied to the edge ring 930 through the first capacitor 960 (C1). The radiofrequency (RF) signal 937 is applied through the second capacitor 962 (C2). The PVT signal 935 is supplied by a first power supply and the RF signal 937 is supplied by a second power supply. Therefore, each power signal may have its own independent power supply. In another example, there may be two PVT power sources to provide for two PVT signals. In this case, a second PVT signal 939 may be applied to the connector 950D in series with the insulator 904. By adding the first capacitor 960 (C1) and the second capacitor 962 (C2), the capacitance of the edge ring 930 may be matched to the capacitance of the substrate 920.

The insulator 904 beneath the cooling plate 906 is beneficial for electrically isolating the cooling system from the rest of the processing chamber 100. Placing the first capacitor 960 (C1) in series with the insulator 904 can help in further stabilizing the electrical environment by providing additional isolation. This can reduce noise and potential interferences with other components of the processing chamber 100. The first capacitor 960 (C1) receives indirect thermal protection, maintaining a stable operating temperature through isolation, whereas the second capacitor 962 (C2) in series with the cooling plate 906 directly benefits from active cooling, thus enhancing thermal management. Placing the second capacitor 962 (C2) in series with the cooling plate 906 may contribute to reducing leakage currents. Thus, the system can achieve a balanced optimization of thermal management and electrical stability, as well as achieving desired capacitance matches between the edge ring 930 and the substrate 920. Further advantages include achieving the same coupling for the center of the substrate 920 and the edge ring 930, achieving a flat (or desired) sheath between the center of the substrate 920 and the edge ring 930, leading to better edge performance, and achieving less arcing near the edge of the substrate 920.

FIG. 9E depicts a simplified capacitance configuration 900E between the substrate 920 and the edge ring 930 within the processing chamber 100 of FIG. 1.

In FIG. 9E, the PVT signal 935 is applied to the DC mesh 914 and the PVT signal 939 is applied to the edge ring 930 through the first capacitor 970 (C1). The radiofrequency (RF) signal 937 is applied through the second capacitor 972 (C2). A connector 950E extends from the edge ring 930 to the cathode 902. The connector 950E is a physical connector, such as a wire, that forms a connection between the first capacitor 970 and the second capacitor 972. The connector 950E may be referred to as a conductor line. The first capacitor 970 (C1) and the second capacitor 972 (C2) may be lumped capacitors.

A pulse voltage technology (PVT) signal 935 is applied to the edge ring 930. A radiofrequency (RF) signal 937 is applied to the cooling plate 906. The PVT signal 935 is supplied by a first power supply and the RF signal 937 is supplied by a second power supply. Therefore, each power signal may have its own independent power supply. In another example, there may be two PVT power sources to provide for two PVT signals. In this case, a second PVT signal 939 may be applied to the connector 950E in series with the cathode 902. By adding the first capacitor 970 (C1) and the second capacitor 972 (C2), the capacitance of the edge ring 930 may be matched to the capacitance of the substrate 920. The capacitance can be about 0.01 to 100 nanofarad (nF).

The first capacitor 970 (C1) is positioned in series with the cathode 902 and a lift pin 975. The lift pin 975 is used to manipulate the position of the substrate 920 during various stages of the deposition/etching process. The lift pin 975 is employed to lift and lower the substrate 920 to and from the susceptor (not shown). The cathode 902 refers to the electrode where the plasma is generated. The lift pin 975 may be constructed near the cathode 902.

Placing the first capacitor 970 (C1) in series with on in the vicinity of the cathode 902 can help stabilize the voltage applied to the cathode 902. By filtering out high-frequency noise and transients, the first capacitor 970 can help reduce electrical noise in the system. This leads to more stable plasma conditions and better process control. The first capacitor 970 can also smooth out fluctuations in the power supply (e.g., PVT power supply) to the cathode 902, leading to a more stable discharge and consistent plasma characteristics. By stabilizing the power delivery to the cathode 902, the first capacitor 970 can help maintain consistent plasma density.

Placing the second capacitor 972 (C2) closer to the cooling plate 906 can help in managing the thermal aspects of the deposition/etching process more effectively. The cooling plate 906 is integral in maintaining the substrate 920 at a desired temperature, and a capacitor in this location can support the thermal management system. Placing the second capacitor 972 (C2) closer to the cooling plate 906 can further enhance thermal stability near the cooling plate to ensure a more consistent temperature across the substrate 920. A capacitor near the cooling plate 906 may also help in dissipating heat more effectively, especially if the capacitor is part of a power supply circuit that generates heat. Moreover, placement of the second capacitor 972 (C2) closer to the cooling plate 906 can provide for better electrical isolation from the deposition/etching area, thus reducing potential interference with the deposition/etching process.

Therefore, the specific needs of the deposition/etching process may dictate the best placement of capacitors. Balancing thermal management and electrical stability may be considered in achieving desired capacitance matches between the edge ring 930 and the substrate 920.

FIG. 9F depicts a simplified capacitance configuration 900F between the substrate 920 and the edge ring 930 within the processing chamber 100 of FIG. 1.

In FIG. 9F, a first capacitor 980 (C1) is coupled to the edge ring 930 and a second capacitor 982 (C2) is coupled to the cooling plate 906. A connector 950F extends from the edge ring 930 to the cathode 902. The connector 950F is a physical connector, such as a wire, that forms a connection between the first capacitor 980 and the second capacitor 982. The connector 950F may be referred to as a conductor line. The first capacitor 980 (C1) and the second capacitor 982 (C2) may be lumped capacitors.

A pulse voltage technology (PVT) signal 935 is applied to the edge ring 930. A radiofrequency (RF) signal 937 is applied to the cooling plate 906. The PVT signal 935 is supplied by a first power supply and the RF signal 937 is supplied by a second power supply. Therefore, each power signal may have its own independent power supply. In another example, there may be two PVT power sources to provide for two PVT signals. In this case, a second PVT signal 939 may be applied to the connector 950F in series with the cathode 902.

By adding the first capacitor 980 (C1) and the second capacitor 982 (C2), the capacitance of the edge ring 930 may be matched to the capacitance of the substrate 920. The advantages of positioning the first capacitor 980 (C1) in series with the edge ring 930 and the second capacitor 982 (C2) in series with the cooling plate 906 were discussed above with reference to FIG. 9A.

In conclusion, FIGS. 9A-9F provide for different configurations for placing capacitors within the processing chamber 100 to achieve a capacitance match between the capacitance of the edge ring 930 and the capacitance of the substrate 920. The capacitance can be about 0.01 to 100 nanofarad (nF). The placement of capacitors within the processing chamber 100 can impact the performance and stability of the deposition/etching process, as well as capacitance matches between various components.

In some configurations, a single capacitor is added. In other configurations, two capacitors are added. The capacitors may be positioned in series with various components of the processing chamber 100. In a first example, one capacitor is placed in series with the edge ring 930 and another capacitor is placed in series with the cooling plate 906. In a second example, one single capacitor is placed in series with the cooling plate 906. In a third example, one single capacitor is placed in series with the edge ring 930. In a fourth example, one capacitor is placed in series with the cooling plate 906 and another capacitor is placed in series with the insulator 904 formed beneath the cooling plate 906. In a fifth example, one capacitor is placed in series with the cathode 902 adjacent the lift pin 975 and another capacitor is placed in series with the cooling plate 906, where a conductor line extends from the edge ring 930 to the cathode 902. In a sixth example, one capacitor is placed in series with the cooling plate 906 and another capacitor is placed in series with the edge ring 930, where a conductor line extends from the edge ring 930 to the cathode 902. Further, the capacitors are powered from different location using multiple power supplies. RF and PVT signals may be concurrently applied from different power sources to different locations. In some examples, multiple PVT signals are applied from multiple locations.

Placing a capacitor in series with the edge ring 930 stabilizes electrical fields near the edge of the substrate, reduces edge effects and promotes uniform deposition or etching, and has a secondary impact on localized heat distribution. Placing a capacitor in series with the cooling plate 906 enhances thermal management and stability, supports consistent substrate temperature, and helps in dissipating heat generated by the capacitor itself. Placing a capacitor in series with the cathode 902 improves voltage stabilization and noise reduction, enhances plasma uniformity and density control, and smoothes out power supply fluctuations. Therefore, by strategically placing capacitors within the processing chamber 100, the capacitance match between the capacitance of the edge ring 930 and the capacitance of the substrate 920 can be optimized.

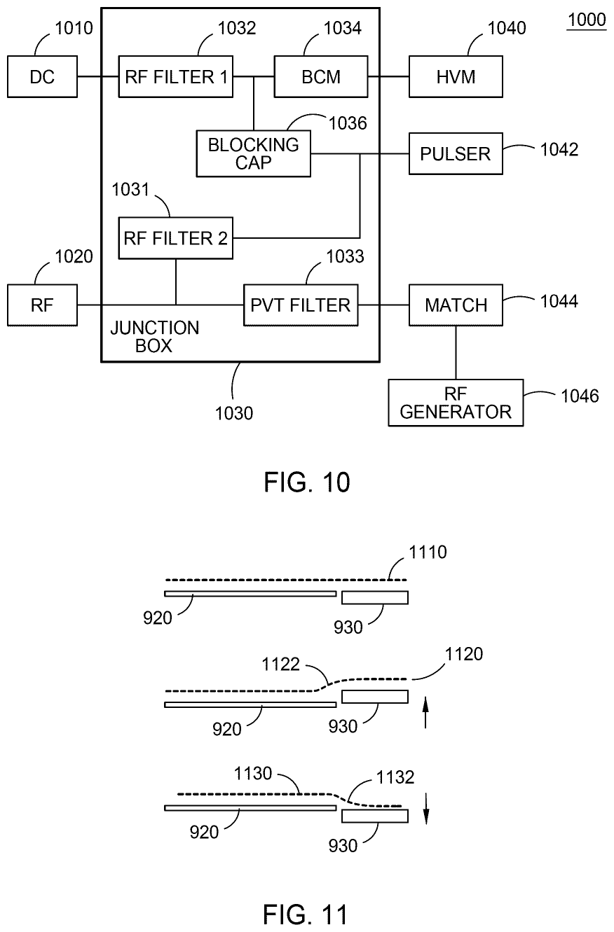

FIG. 10 illustrates a circuit configuration 1000 for balancing capacitance values within a processing chamber, according to one implementation.

The circuit configuration 1000 shows a junction box 1030 having a first output 1010 to the DC mesh 914 and a second output 1020 to the cooling plate 906. The first output 1010 may be a direct current (DC) input and the second output 1020 may be a RF input. The first output 1010 is output by a first RF filter 1032 coupled to a compensation module 1034 and a blocking cap 1036. The compensation module 1034 is coupled to the high voltage module (HVM) 1040. The blocking cap 1036 is coupled to the pulser 1042. The pulser 1042 generates pulses. The second output 1020 is output by a second RF filter 1031 and a PVT filter 1033. The PVT filter 1033 is coupled to an impedance matching circuit 1044 coupled to an RF generator 1046.

Therefore, the circuit configuration 1000 shows that the junction box 1030 can accommodate both RF signals and PVT signals received from two different power supplies. The PVT is sent to both the mesh and the baseplate.

FIG. 11 illustrates movement of an edge ring when balancing capacitance values within a processing chamber, according to one implementation.

In the first schematic, the substrate 920 is shown adjacent the edge ring 930. A plasma sheath over the substrate 920 and the edge ring 930 has a substantially flat profile 1110.

In the second schematic 1120, the substrate 920 is shown adjacent the edge ring 930. A plasma sheath over the substrate 920 and the edge ring 930 depicts an upward bent profile 1122. This is caused because of the movement of the edge ring 930. In this example, the edge ring 930 moved upward causing the plasma sheath to bend in an upward direction. If the edge ring 930 is raised, this can result in a thicker plasma sheath near the edge of the substrate 920, affecting the uniformity of the plasma. The upward movement of the edge ring 930 may cause the electric field lines to become more concentrated near the edge of the substrate 920, which can enhance edge effects, where the deposition/etching rates and film properties differ at the substrate edges compared to the center of the substrate 920.

In the third schematic 1130, the substrate 920 is shown adjacent the edge ring 930. A plasma sheath over the substrate 920 and the edge ring 930 depicts a downward bent profile 1132. This is caused because of the movement of the edge ring 930. In this example, the edge ring 930 moved downward causing the plasma sheath to bend in a downward direction. If the edge ring 930 is lowered, this can result in a thinner plasma sheath near the edge of the substrate 920, which may reduce the electric field intensity and lead to non-uniform plasma distribution. The downward movement of the edge ring 930 may cause the electric field distribution to be non-uniform.

As a result, the movement of the edge ring 930 should be carefully controlled and optimized based on the specific deposition/etching process requirements.

The edge ring 930 surrounds the substrate 920. The movement of the edge ring 930, which can move upward or downward, plays a role in influencing the plasma sheath formed above the edge ring 930 and the substrate 920. When the edge ring 930 moves in an upward direction, the edge ring 930 effectively raises the boundary of the substrate's surface area that interacts with the plasma. When the edge ring 930 moves in a downward direction, the edge ring 930 lowers the boundary of the substrate's surface area changing the interaction dynamics between the edge of the substrate 920 and the plasma. The plasma sheath is a thin layer of particles that form at the interface between the plasma and a solid surface, such as the substrate 920 and the edge ring 930. The movement of the edge ring can influence the characteristics of the plasma sheath.

The objective is to achieve a substantially flat profile 1110 by matching the capacitance of the substrate 920 to the capacitance of the edge ring 930 whether PVT signals or RF signals are applied. As such, movement of the edge ring 930 may be taken into consideration when attempting to match the capacitances of the edge ring 930 and the substrate 920. The capacitance can be about 0.01 to 100 nanofarad (nF). Process engineers may fine-tune the capacitances in the processing chamber 100 to achieve the desired outcomes to enhance the quality and uniformity of the films deposited on substrates.

Additionally, the edge ring 930 is not coated in the second approach.

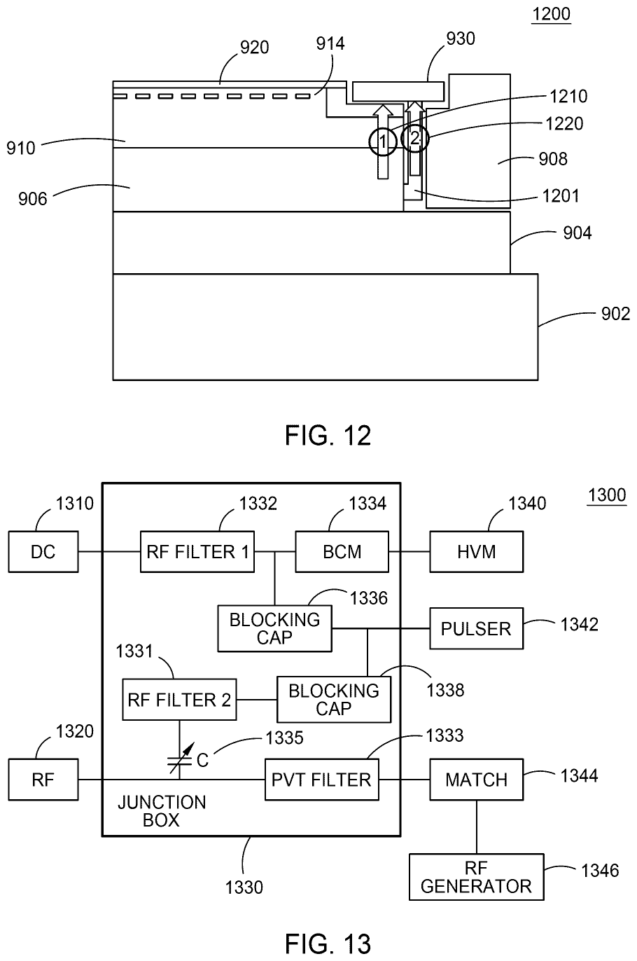

FIGS. 12-18 describe an embodiment for modulating the capacitance to the edge ring. The capacitance of the edge ring 930 is modulated to match the capacitance of the substrate 920. FIGS. 12-18 present a third approach where the capacitors are variable capacitors. The variable capacitors have a capacitance value that can be adjusted manually or electronically. In contrast to the first and second approaches presented above based on FIGS. 1-11, the edge ring 930 does not moves or is not shifted when balancing the capacitance of the edge ring 930 to the capacitance of the substrate 920. Additionally, the edge ring 930 is not coated in the third approach.

FIG. 12 illustrates a variable capacitance configuration for balancing capacitance values within a processing chamber, according to one implementation.

The circuit configuration 1200 includes the insulator 904 formed over the cathode 902. The cooling plate 906 is formed over the insulator 904. The cooling plate 906 is used to manage the temperature of the substrate 920 during the process. The ESC 910 is placed over the cooling plate 906. The ESC 910 includes the DC mesh 914. The ESC 910 is used to hold the substrate 920 in place during the process. The ESC 910 uses electrostatic forces to secure the substrate 920 firmly thereon. The insulator 904 is placed between the cooling plate 906 and the cathode 902 to electrically isolate the two components. A connector 1201 extends between the cooling plate 906 and the edge ring 930. The edge ring 930 is placed adjacent to the substrate 920. In one example the edge ring 930 is constructed from silicon carbide (SiC). The edge ring 930 is supported by the insulator material 908. The insulator material 908 rests between the edge ring 930 and the susceptor (not shown) to electrically isolate the edge ring 930 from the susceptor. The edge ring 930 is fixed in place and is free of coatings. The objective of this structure is to match the capacitance of the edge ring 930 to the capacitance of the substrate 920.

Arrow 1210 indicates a first area where capacitance differences are detected. Arrow 1220 indicates a second area where capacitance differences are detected. Capacitive or capacitance differences may cause inconsistent plasma sheath formation. Capacitive differences can affect the formation and stability of the plasma sheath near the substrate 920 and the edge ring 930. A stable plasma sheath is beneficial for substrate process results. Inconsistent plasma sheath formation may cause irregularities in the process, resulting in defects or non-uniform films. Also, the edge ring 930 may suffer from irregular ion bombardment, leading too uneven erosion or deposition on the edge ring 930, which may affect its effectiveness in maintaining process uniformity. Capacitive differences may further cause arcing and electrical noise in the processing chamber 100. Arcing may cause localized damage and introduce contaminants. Arcing may create defects on the surface of the substrate 920, such as pits or irregularities, thus compromising the integrity of the deposited films. Electrical noise may interfere with plasma stability. Also, the edge ring 930 may be subjected to additional stress due to electrical noise, potentially leading to faster degradation or failure.

Such capacitive differences may be mitigated or prevented by strategically adding one or more capacitors within the processing chamber 100. In the examples of FIGS. 13-18, one or more variable capacitors may be added within the processing chamber 100 to match the edge ring capacitance to the capacitance of the substrate. Each variable capacitor may be coupled to a separate power source. Stated differently, each variable capacitor may be independently powered by either an RF power source or a pulse generator (i.e., PVT).

FIG. 13 illustrates a circuit configuration with a single variable capacitor, according to one implementation.

The circuit configuration 1300 shows a junction box 1330 having a first output 1310 to the DC mesh 914 and a second output 1320 to the cooling plate 906. The first output 1310 may be a DC input and the second output 1320 may be a RF input. The first output 1310 is output by a first RF filter 1332 coupled to a compensation module 1334 and a blocking cap 1336. The compensation module 1334 is coupled to the high voltage module (HVM) 1340. The compensation module 1334 stabilizes the first output 1310 (i.e., the DC input). The blocking cap 1336 is coupled to the pulser 1342. The pulser 1342 generates pulses. The second output 1320 is output by a second RF filter 1331 and a PVT filter 1333. The PVT filter 1333 is coupled to an impedance matching circuit 1344 coupled to an RF generator 1346. However, in contrast to the circuit configuration 1000 of FIG. 10, a variable capacitor 1335 is positioned between the second RF filter 1331 and the PVT filter 1333. Additionally, a blocking cap 1338 is coupled to the second RF filter 1331. The variable capacitor 1335 is added in the junction box 1330 between the power supply (e.g., the second output 1320) and the edge process kit to provide for edge control. The variable capacitor 1335 may be driven by, e.g., a motor, a bias voltage, or other mechanisms (not shown). In some examples, an inductor or other electrical component may also be added for tuning and filtering purposes.

The edge ring 930 does not move in the circuit configuration 1300 because the variable capacitor 1335 can be employed to adjust the plasma sheath characteristics.

Also, the edge ring 930 is not coated when a variable capacitor is used. The reasons for coating the edge ring 930 include, e.g., protection against corrosion and wear, minimizing particle contamination, improving process uniformity, and thermal management considerations. However, the coating of the edge ring 930 may affect the edge ring coupling. As such, no coating is applied because it is desired to adjust the edge ring coupling using the variable capacitor 1335. In other words, the coating may adversely affect the operation of the variable capacitor 1335.

Therefore, the circuit configuration 1300 shows that the junction box 1330 can accommodate both RF signals and PVT signals received from two different power supplies. The PVT is sent to both the mesh and the baseplate.

Additionally, adding the variable capacitor 1335 provides for enhanced control over the edge effects during the process. The variable capacitor 1335 allows for fine-tuning of the impedance between various components. By adjusting the capacitance using the variable capacitor 1335, the electrical properties at the edge of the substrate 920 can be controlled more precisely. This helps in managing the distribution of the electric field and plasma density near the edges, which is beneficial for uniform process results. Further, the plasma sheath, which forms over the substrate 920 and the edge ring 930, is influenced by the electrical conditions in the processing chamber 100. The variable capacitor 1335 can be used to modify the local electric field, thus adjusting the sheath properties. This may lead to a reduction of unwanted edge effects. Also, by dynamically adjusting the capacitance using the variable capacitor 1335, variations in the electric field and plasma density may be mitigated, leading to more uniform film thickness and properties across the substrate 920.

In one example, the variable capacitor 1335 can be adjusted in real-time during the process. This allows for immediate compensation for any changes in the plasma characteristics or power supply variations. Also, by adjusting the capacitance, the system can be fine-tuned to achieve electrical resonance at specific frequencies. This resonance enhances the coupling of RF power to the plasma, improving plasma stability and uniformity. As such, the variable capacitor 1335 can optimize power delivery to the substrate 920 and the edge ring 930. The variable capacitor 1335 may further provide the flexibility to adapt to various process requirements without needing hardware changes. Thus, different materials and process conditions that may involve different capacitance settings may be accommodated. Finally, real-time capacitance adjustments help in maintaining stable process conditions, thus reducing the likelihood of process deviations and ensuring consistent results across multiple runs.

In conclusion, edge ring coupling may be controlled electrically instead of mechanically, and the capacitance of the edge ring 930 may be successfully matched with the capacitance of the substrate 920. The variable capacitor 1335 provides for accurate control and compatibility with a fixed or movable process kit, as described above with reference to FIG. 1. The variable capacitor 1335 also better controls sheath bending. As such, sheath bending is controlled electrically instead of mechanically. Finally, the variable capacitor 1335 may be used to modify plasma sheath characteristics to reduce edge effects and achieve uniform process results, as well as match a capacitance of the edge ring 930 to a capacitance produced between the DC mesh 914 and the substrate 920. As such, the edge ring 930 does not need to be moved in an upward or downward direction adjust the plasma sheath because the variable capacitor 1335 takes on that role of adjusting the plasma sheath characteristics.

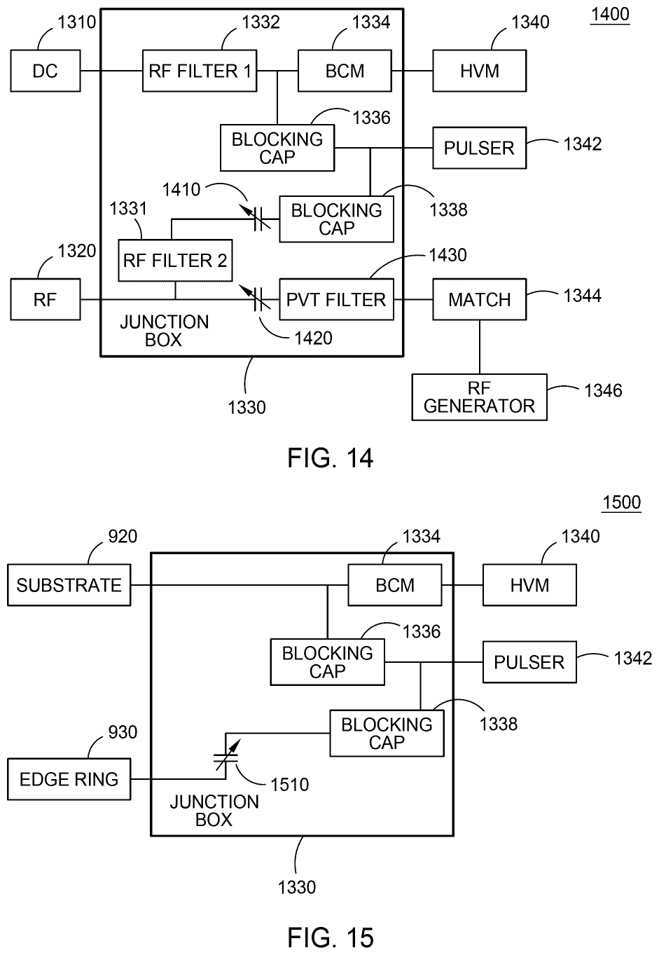

FIG. 14 illustrates a circuit configuration with two variable capacitors, according to one implementation.

The circuit configuration 1400 shows the junction box 1330 having a first output 1310 and a second output 1320. The first output 1310 may be a DC input and the second output 1320 may be a RF input. The first output 1310 is output by a first RF filter 1332 coupled to a compensation module 1334 and a blocking cap 1336. The compensation module 1334 is coupled to the HVM 1340. The blocking cap 1336 is coupled to the pulser 1342. The pulser 1342 generates pulses. The second output 1320 is output by a second RF filter 1331 and a PVT filter 1333. The PVT filter 1333 is coupled to an impedance matching circuit 1344 coupled to an RF generator 1346. However, in contrast to the circuit configuration 1300 of FIG. 13, a first variable capacitor 1410 is positioned between the second RF filter 1331 and the blocking cap 1338. Additionally, a second variable capacitor 1420 is positioned between the second RF filter 1331 and the PVT filter 1333. Also, a blocking cap 1338 is coupled to the second RF filter 1331. The first variable capacitor 1410 is used for a first frequency and the second variable capacitor 1420 is used for a second frequency. The first frequency is for the PVT and the second frequency is for the RF. The first frequency may be, e.g., about 400 kHz and the second frequency may be, e.g., about 13 MHz.

The first variable capacitor 1410 and the second variable capacitor 1420 are added in the junction box 1330 between the power supply (e.g., the second output 1320) and the edge process kit to provide for edge control. The first variable capacitor 1410 and the second variable capacitor 1420 may be driven by, e.g., a motor, a bias voltage, or other mechanisms (not shown). In some examples, an inductor or other electrical component may also be added for tuning and filtering purposes. The first variable capacitor 1410 and the second variable capacitor 1420 may be driven by independent supplies or mechanisms.

The edge ring 930 does not move in the circuit configuration 1400 because the first variable capacitor 1410 and the second variable capacitor 1420 can be employed to adjust the plasma sheath characteristics.

Also, the edge ring 930 is not coated when a variable capacitor is used.

Therefore, the circuit configuration 1400 shows that the junction box 1330 can accommodate both RF signals and PVT signals received from two different power supplies. The PVT is sent to both the mesh and the baseplate.

In conclusion, edge ring coupling may be controlled electrically instead of mechanically, and the capacitance of the edge ring 930 may be successfully matched with the capacitance of the substrate 920. The first variable capacitor 1410 and the second variable capacitor 1420 provide for accurate control and compatibility with a fixed or movable process kit, as described above with reference to FIG. 1. The first variable capacitor 1410 and the second variable capacitor 1420 also better control sheath bending. As such, sheath bending is controlled electrically instead of mechanically. Finally, the first variable capacitor 1410 and the second variable capacitor 1420 may be used to modify plasma sheath characteristics to reduce edge effects and achieve uniform process results. The first variable capacitor 1410 matches the capacitance between the DC mesh 914 and the substrate 920. The second variable capacitor 1420 matches the capacitance between the cooling plate 906 and the substrate 920. As such, the edge ring 930 does not need to be moved in an upward or downward direction adjust the plasma sheath because the first variable capacitor 1410 and the second variable capacitor 1420 take on that role of adjusting the plasma sheath characteristics.

FIG. 15 illustrates a circuit configuration with one variable capacitor and one energy source, according to one implementation.

The circuit configuration 1500 shows the substrate 920 and the edge ring 930 coupled to the junction box 1330. The RF and PVT filters have been removed and only a single power source is employed. The substrate 920 is coupled to the compensation module 1334, the blocking cap 1336, and the blocking cap 1338. The compensation module 1334 is coupled to the HVM 1340. The blocking cap 1336 and the blocking cap 1338 are coupled to the pulser 1342. The pulser 1342 generates pulses. The edge ring 930 is coupled to a variable capacitor 1510, which in turn is coupled to the blocking cap 1338.

The edge ring 930 does not move in the circuit configuration 1500 because the variable capacitor 1510 can be employed to adjust the plasma sheath characteristics.

Also, the edge ring 930 is not coated when a variable capacitor is used.

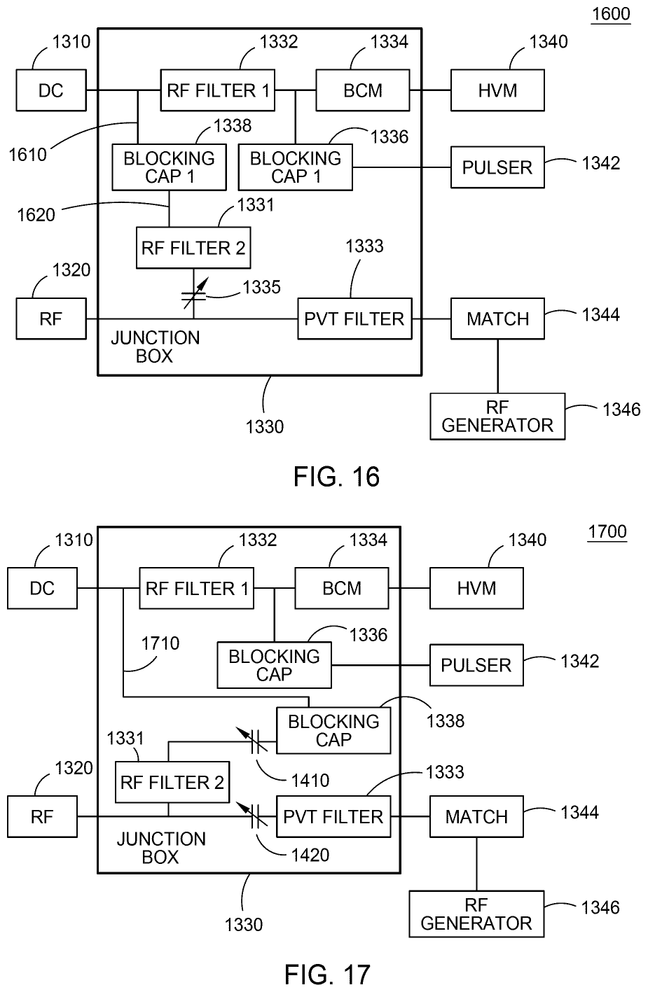

FIG. 16 is an alternative circuit configuration shown in FIG. 13 with a single variable capacitor, according to another implementation.

The circuit configuration 1600 shows an alternative embodiment to FIG. 13. A detailed description of similar elements to FIG. 13 will be omitted. In the circuit configuration 1600, the main difference compared to FIG. 13 is that the blocking cap 1338 is coupled via connection 1610 between the first output 1310 and the first RF filter 1332. Additionally, the second RF filter 1331 is coupled via connection 1620 directly to the blocking cap 1338 instead of the blocking cap 1336. The connection between the pulser 1342 and the blocking cap 1338 is thus cut off.

The edge ring 930 does not move in the circuit configuration 1600 because the variable capacitor 1335 can be employed to adjust the plasma sheath characteristics.

Also, the edge ring 930 is not coated when a variable capacitor is used.

FIG. 17 is an alternative circuit configuration shown in FIG. 14 with two variable capacitors, according to another implementation.

The circuit configuration 1700 shows an alternative embodiment to FIG. 14. A detailed description of similar elements to FIG. 14 will be omitted. In the circuit configuration 1700, the main difference compared to FIG. 14 is that the blocking cap 1338 is coupled via connection 1710 between the first output 1310 and the first RF filter 1332. The connection between the pulser 1342 and the blocking cap 1338 is thus cut off.

The edge ring 930 does not move in the circuit configuration 1700 because the first variable capacitor 1410 and the second variable capacitor 1420 can be employed to adjust the plasma sheath characteristics.

Also, the edge ring 930 is not coated when a variable capacitor is used.

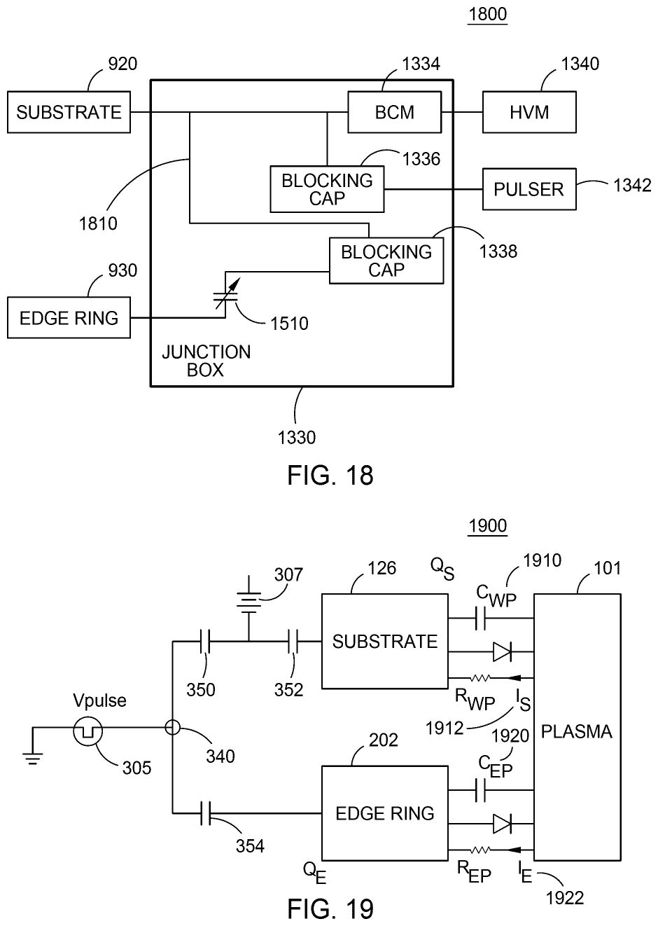

FIG. 18 is an alternative circuit configuration shown in FIG. 15 with one variable capacitor and one energy source, according to another implementation.

The circuit configuration 1800 shows an alternative embodiment to FIG. 15. A detailed description of similar elements to FIG. 15 will be omitted. In the circuit configuration 1800, the main difference compared to FIG. 15 is that the blocking cap 1338 is coupled via connection 1810 between the substrate 920 and the compensation module 1334. The connection between the pulser 1342 and the blocking cap 1338 is thus cut off.

The edge ring 930 does not move in the circuit configuration 1800 because the variable capacitor 1510 can be employed to adjust the plasma sheath characteristics.

Also, the edge ring 930 is not coated when a variable capacitor is used.

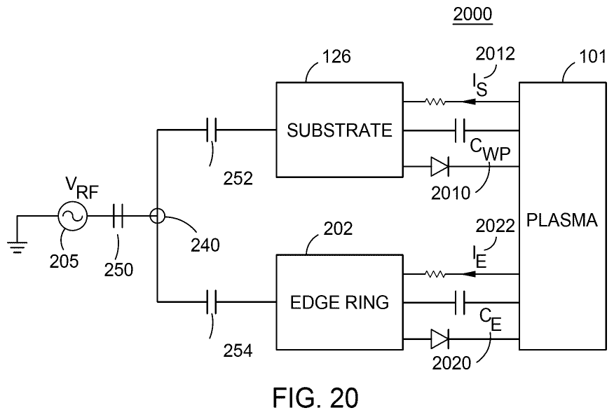

FIG. 19 is a circuit for balancing the process kit area (edge ring area) to match the wafer area where PVT is used, according to one implementation and FIG. 20 is a circuit for balancing the process kit area (edge ring area) to match the wafer area where RF power is used, according to another implementation.

Circuit 1900 of FIG. 19 shows the plasma 101 generated by applying a signal from, e.g., the pulse generator 305 in cooperation with the battery 307. The pulse generator 305 applies a voltage in a series of short, high-intensity pulses rather than a continuous wave. The first capacitance 350 may be placed in series with the cooling plate 906 (FIGS. 9A-9F). The second capacitance 352 may be placed in series with the DC mesh 914 of the ESC 910 (FIGS. 9A-9F). The third capacitance 354 may be placed in series with the insulator material 908 positioned adjacent the edge ring 202. The point 340 may be referred to as a modulating point. The second capacitance 352 is coupled to the substrate 126 and the third capacitance 354 is coupled to the edge ring 202. A capacitance between the substrate 126 and the plasma 101 is designated as capacitance (C_{wp}) 1910. A capacitance between the edge ring 202 and the plasma 101 is designated as capacitance (Cₑₚ) 1920. The capacitance (C_{wp}) 1910 is matched with the capacitance (Cₑₚ) 1920 by making the area of the wafer equal to the area of the edge ring. As such, capacitance disparities between capacitance (C_{wp}) 1910 and capacitance (Cₑₚ) 1920 are significantly minimized, reduced or completely eliminated.

Also, during discharging, the total current Iₛ 1912 between the substrate 126 and the plasma 101 should match the total current I_{E} 1922 between the edge ring 202 and the plasma 101. The current between the plasma and a surface represents the rate of charge exchange at that interface. If the current to the wafer (Iₛ) is significantly different from the current to the edge ring (I_{E}), it can lead to charge imbalances. A mismatched current distribution may create uneven electric fields. Thus, matching the current between the wafer and plasma with the current between the edge ring and plasma is beneficial for balancing plasma dynamics and ensuring uniform processing. It can minimize edge effects, stabilize sheath potentials, and support efficient power delivery.

Further, for ion current discharge of capacitors C_{wp} and Cₑₚ, the same current ion current density is expected. If the paths of capacitances 350, 352 are the same as the path for capacitance 354, then the substrate 126 and the edge ring 202 will charge to the same voltage. In other words, they will have the same total charge (Q). Thus, at the beginning of the pulse, the charge will be the same (Q_{S}=Q_{E}). The charge is dissipated by the ion current, given as I=Q/t. However, to discharge Q_{S} and Q_{E} at the same rate, the I_{S} and I_{E} need to be the same, that is, I_{S}=I_{E}. As such, it is also beneficial for achieving a match of the current between the substrate 126 and plasma 101 and the current between the edge ring 202 and plasma 101. Similarly, the current density (J) of the current between the substrate 126 and the plasma 101, and the current between the edge ring 202 and the plasma 101 should be matched, that is, J_{S}=J_{E.}

In PVT systems, the plasma is energized using pulsed voltages instead of continuous RF power. The voltage is applied in periodic pulses, allowing the system to alternate between active power application and relaxation phases. This method is used to improve process precision and reduce damage to the wafer. Matching the wafer area to the edge ring area in PVT is beneficial. Benefits of matching in a PVT system include ensuring the sheath potential evolves uniformly during both pulse and relaxation phases, balancing ion energy and flux to enhance control over etching or deposition rates, preventing localized overcharging or undercharging, reducing the risk of wafer defects or damage, and minimizing plasma oscillations or density fluctuations caused by unbalanced discharges.

Circuit 2000 of FIG. 20 shows the plasma 101 generated by applying a signal from, e.g., the RF generator 205. The RF generator 205 generates high-frequency electrical signals used to ionize the process gases to create the plasma 101. The processing chamber 100 includes several capacitances at various locations. The first capacitance 250 may be placed in series with the cathode 902 (FIGS. 9A-9F). The second capacitance 252 may be placed in series with the cooling plate 906 (FIGS. 9A-9F). The third capacitance 254 may be placed in series with the insulator material 908 positioned adjacent the edge ring 202. The point 240 may be referred to as a modulating point. The point 240 is in series with the first capacitance 250 and the second capacitance 252. The second capacitance 252 is coupled to the substrate 126 and the third capacitance 254 is coupled to the edge ring 202. A capacitance between the substrate 126 and the plasma 101 is designated as capacitance (Cwp) 2010. A capacitance between the edge ring 202 and the plasma 101 is designated as capacitance (Cep) 2020. The capacitance (Cwp) 2010 is matched with the capacitance (Cep) 2020 by making the area of the wafer equal to the area of the edge ring. As such, capacitance disparities between capacitance (Cwp) 2010 and capacitance (Cep) 2020 are significantly minimized, reduced or completely eliminated.

If the second capacitance 252 and the third capacitance 254 are the same, then the edge ring 202 and the substrate 126 will have the same DC voltage and the same charge, Q. When the RF bias voltage from the RF generator 205 turns off, the substrate 126 and the edge ring 202 will discharge from the plasma ion current. In order to discharge or dissipate the same charge, the ion current needs to be the same. If the same initial plasma voltage is assumed, then the ion density will be the same. In order to have the same ion current, the capacitance (Cwp) 2010 and the capacitance (Cep) 2020 need to be the same. As such, the areas also need to be the same.

In RF-powered plasma systems, alternating current (AC) is applied at radio frequencies to generate and sustain the plasma. The wafer and edge ring act as electrodes or capacitive elements in this system, with the plasma serving as the medium through which energy is transferred. Matching the wafer area to the edge ring area ensures that the discharge dynamics remain uniform, improving process stability and outcomes. Benefits of matching in an RF system include ensuring the plasma density is evenly distributed across the wafer and edge ring, balancing the sheath potential to reduce variability in ion flux, reducing the complexity of RF power tuning to minimize energy losses, and balancing the electric field at the wafer's edges, preventing localized over-etching or deposition.

Therefore, matching the wafer area to the edge ring area is beneficial in both RF-powered and PVT plasma systems for ensuring balanced discharging. In RF systems, it promotes uniform plasma density, simplifies power delivery, and reduces edge effects. In PVT systems, it stabilizes sheath dynamics during pulse and relaxation phases, improving precision and reducing wafer damage. Regardless of the power application method, balancing the wafer and edge ring areas ensures consistent and high-quality process outcomes.

The wafer area refers to the surface area of the semiconductor wafer that is being processed. A wafer is a thin slice of semiconductor material (typically silicon) used to fabricate integrated circuits (ICs). The wafer area is determined by the diameter of the wafer, which can vary in size (e.g., 200 mm, 300 mm, or even larger for advanced nodes). For example, a 300 mm wafer has a surface area of approximately 70,685 square millimeters. The wafer area is where processes like etching, deposition, lithography, or cleaning are performed. Uniformity and quality of processes across the entire wafer area ensure consistent device performance and high yield.

The edge ring area refers to the surface area of the edge ring that is exposed to the plasma and participates in the electrical interactions within the chamber. The edge ring is a component surrounding the wafer, designed to confine the plasma, minimize edge effects, and enhance process uniformity. Its exposed area contributes to the total capacitance between the plasma and the edge ring, impacting how charges are stored and discharged during the plasma process. The edge ring area is influenced by the physical dimensions of the edge ring, including its width, thickness, and shape. The edge ring area also depends on how the edge ring is positioned relative to the wafer and the chamber walls. The exposed surface area directly facing the plasma is the most significant contributor to capacitance, although fringing effects along the edges of the ring can also play a role.

Capacitance differences in plasma processing systems can influence the uniformity and effectiveness of the process. In systems where a wafer and an edge ring are used, disparities in discharge rates between their respective capacitances can lead to non-uniform plasma behavior, which may degrade the process quality. Discharging refers to the sudden release of this accumulated charge, either by direct grounding, natural neutralization, or an uncontrolled electrostatic discharge (ESD). Discharge can happen intentionally (via designed grounding paths) or unintentionally when the accumulated charge reaches a critical threshold and discharges rapidly, which can cause equipment damage or process issues. If the accumulated charge discharges suddenly (e.g., via arcing), it can cause damage to the wafer being processed.

The discharge rate of capacitance is governed by the RC time constant, where R represents resistance and C is the capacitance. If the capacitance or resistance associated with the wafer differs significantly from that of the edge ring, the time constants for energy discharge will differ. This disparity means that the wafer's stored charge may dissipate at a different rate compared to the edge ring. The result is an imbalance in the plasma sheath, which can cause non-uniform electric fields and ion flux distributions.

In a plasma reactor, the sheath is the region near a surface where the electric field accelerates ions toward the material. When the discharge rates differ, the sheath potential near the wafer and edge ring becomes uneven. This unevenness can lead to localized variations in ion energy and density, which may cause issues such as etch rate non-uniformity, damage to sensitive features, or uneven deposition profiles.

In one non-limiting example, the wafer and the edge ring can both charge at the same rate of 10 coulombs per second, but their discharge rates differ, that is, the wafer discharges at 1 coulomb per second, while the edge ring discharges at only 0.5 coulombs per second. As a result, the wafer fully discharges in 10 seconds, but the edge ring requires 20 seconds to reach the same state. This mismatch creates an issue in maintaining uniform plasma conditions, as it disrupts the balance of electric fields and ion flux across the surface.

The discharge rates of the wafer and edge ring help maintain a stable plasma sheath. When the wafer discharges faster than the edge ring, the potential difference between the two surfaces changes over time. Initially, the sheath potential near the wafer and edge ring may be uniform, but as the wafer discharges more quickly, its sheath potential decreases faster than that of the edge ring. This results in an uneven electric field distribution, which can cause ions to accelerate non-uniformly across the plasma, leading to non-uniform etching or deposition on the wafer.

The uneven discharge rates may also create a localized imbalance in the plasma ion flux. Since ions are influenced by the electric field, the region near the wafer may experience a higher ion bombardment initially, while the edge ring maintains a stronger electric field for a longer time due to its slower discharge. This imbalance can lead to over-etching or under-etching near the wafer edges or non-uniform deposition patterns, degrading process quality.

This mismatch can further lead to issues during plasma processing. For example, in processes like etching or deposition, precision is critical. The faster-discharge rate of the wafer may result in a rapid change in plasma behavior near the wafer surface, causing instability. Meanwhile, the slower discharge of the edge ring could maintain an inconsistent plasma environment over a prolonged period, making it challenging to achieve uniform processing outcomes. Moreover, in one example, as the edge ring may take twice as long to discharge, it could maintain a residual charge that interferes with subsequent process steps.

One approach to mitigate the different discharge rates between the wafer and the edge ring is to match the area of the wafer to the area of the edge ring. Mitigating the disparity in discharge rates between the wafer and the edge ring by making their areas equal is a strategic approach to addressing the imbalance in capacitance. Since capacitance is directly proportional to the surface area of the conductor facing the plasma, equalizing the areas of the wafer and edge ring ensures that they store and discharge charges at similar rates. This adjustment aligns the RC time constants of the two components, promoting uniform plasma behavior.

Capacitance (C) between two conducting surfaces separated by a dielectric (such as plasma) is governed by the equation:

C=∈x (A/d)
where, ∈ is the permittivity of the medium (plasma), A is the surface area of the conductor, and d is the distance between the surfaces.

Capacitance is determined by factors such as the material properties, distance between the surfaces, and the area of the exposed surface. For the wafer and edge ring, the capacitance to the plasma is proportional to their exposed areas. A larger surface area corresponds to higher capacitance, which results in slower charge and discharge rates for a given resistance. When the wafer and edge ring have different areas, their capacitances differ, leading to disparities in how quickly each component can discharge relative to the plasma. Aligning or matching the areas ensures that both components exhibit similar capacitances, making their discharge behavior consistent. As such, when the surface areas of the wafer and edge ring are unequal, their capacitances differ. A larger surface area results in higher capacitance, leading to a slower discharge rate for the same resistance. By making the wafer's area equal to the edge ring's area, their capacitances are matched, ensuring balanced discharge behavior.

Equalizing or matching the wafer and edge ring areas helps stabilize the plasma sheath. Since the capacitance directly influences the rate at which charge is stored and discharged, matching the areas ensures that the sheath potentials near the wafer and edge ring change at the same rate. This prevents the development of uneven electric fields that may cause non-uniform ion acceleration and distribution across the wafer's surface.

When the discharge rates of the wafer and edge ring are equalized or matched, the ion flux across the plasma remains uniform. This uniformity helps achieve consistent etching or deposition rates across the wafer. In applications where feature sizes are shrinking and process tolerances are increasingly tight, even minor variations in ion flux can lead to significant defects or yield losses.

An imbalanced discharge can result in over-etching near the wafer's edges or the introduction of non-uniform deposition patterns. By matching the areas and capacitances, such disparities are minimized. This reduces process-induced defects, enhancing the reliability and quality of the final product.

Therefore, discharge rates are important because discharge rates impact the stability of the plasma sheath (i.e., the thin region near the wafer and edge ring where electric fields control ion movement). If the wafer discharges more quickly than the edge ring, the sheath potential near the wafer decreases faster, causing uneven electric fields. This can lead to non-uniform ion bombardment, which affects etching depth, deposition rates, or the uniformity of the plasma process across the wafer surface. Matching the wafer and edge ring areas balances the discharge rates, ensuring that the sheath potential evolves uniformly. This promotes consistent electric fields, resulting in uniform ion fluxes and plasma behavior throughout the chamber.

In one example, suppose a wafer has an exposed surface area of 300 cm², while the edge ring has an exposed area of 200 cm². The wafer's capacitance to the plasma would be higher, resulting in a slower discharge rate. This imbalance may cause the wafer's electric potential to drop faster than the edge ring's, disrupting the uniformity of the plasma sheath. By increasing the edge ring's area to match the wafer's (e.g., widening the edge ring or using additional edge components), the capacitances can be matched. Both the wafer and edge ring would then store and release charge at similar rates, maintaining a stable and uniform plasma sheath.

Matching the wafer area to the edge ring area is beneficial for achieving equal discharge rates, which leads to numerous benefits in plasma-based processes. The benefits may include uniform plasma sheath dynamics, consistent ion flux distribution, reduction in edge effects, improved process precision, enhanced plasma stability, minimized localized damage, and higher process yield.

The plasma sheath forms at the interface between the plasma and the surfaces of the wafer and edge ring. This sheath controls ion flux and energy during plasma processing. When the discharge rates are equal, the sheath potential remains consistent across the wafer and edge ring, ensuring uniform electric fields.

Equal discharge rates ensure that the wafer and edge ring experience the same rate of charge neutralization. This balance maintains a steady ion flux density across both surfaces, avoiding variations in processing outcomes. A consistent ion flux is beneficial for achieving even material removal or deposition.

Edge effects, such as over-etching or uneven deposition, occur when the electric field and plasma density vary between the wafer's edges and the center. Matching the wafer and edge ring areas balances the discharge rates, minimizing these effects. This ensures that the edge ring effectively mitigates uneven plasma interactions at the wafer edges, improving overall process uniformity.

Plasma systems are sensitive to changes in surface charge and capacitance. Unequal discharge rates can cause oscillations or instabilities in plasma density and sheath potential. Matching the wafer and edge ring areas promotes stable discharge dynamics, reducing the risk of plasma instabilities that may degrade the process quality.

Localized hotspots or overcharging can occur if one component discharges faster or slower than the other. These discrepancies can lead to wafer defects, such as micro-cracks or uneven stress distribution. Balancing the discharge rates ensures that both the wafer and edge ring interact with the plasma uniformly, reducing the likelihood of such damage.

Uniform discharge further leads to consistent processing across the wafers, reducing variability and defects. This improves process yield, as fewer wafers are discarded due to quality issues. High yields help maintain cost-efficiency and meeting production targets in semiconductor manufacturing.

In conclusion, modulating the capacitance of the edge ring in relation to the substrate capacitance in a processing chamber is beneficial for improving film uniformity, enhancing process control, reducing particulate contamination, ensuring better step coverage, optimizing deposition/etch rates, maintaining plasma stability, improving energy efficiency, and allowing customization for different materials. These benefits collectively contribute to higher quality thin-film deposition/etching and more efficient processes. Three different approaches are presented to modulate the capacitance of the edge ring to match the capacitance of the substrate (i.e., the capacitance produced between the DC mesh of the electrostatic chuck (ESC) and the substrate). The first approach involves adjusting the capacitance based on a number of parameters, such as gaps and distance between components. The edge ring moves or is shifted when balancing the capacitance of the edge ring to the capacitance of the substrate. The second approach involves using fixed capacitors with set capacitance values. Similarly to the first approach, the edge ring moves or is shifted when balancing the capacitance of the edge ring to the capacitance of the substrate. The third approach involves using a variable capacitor. In contrast to the first and second approaches, the edge ring is fixed in place and does not move or shift during capacitance balancing. Further, in the first approach the edge ring includes a coating, whereas in the second and third approaches the edge ring does not include a coating. Each of the three different approaches enable capacitance rebalancing within the processing chamber.

In conclusion, matching the wafer area to the edge ring area is a technique used to ensure that the wafer and edge ring discharge at the same rate relative to the plasma during semiconductor manufacturing processes. This approach addresses disparities in capacitance, which directly affect how charges are stored and released in the wafer and edge ring. By aligning the surface areas exposed to the plasma, the system achieves balanced capacitances, leading to uniform electric field behavior and consistent plasma interaction. This strategy is beneficial in processes like plasma etching or deposition, where uniformity is critical for maintaining high-quality results. Mismatched discharge rates can cause uneven electric fields, leading to non-uniform ion fluxes that degrade the process outcomes. Matching the areas helps mitigate these issues and promotes a stable plasma environment. Balanced discharge rates ensure uniform electric fields and ion fluxes across the wafer, improving process consistency. Equalizing or matching areas minimizes over-etching or uneven deposition, reducing defects and enhancing yield. With matched capacitances, the RF and the PVT power delivery systems operates more efficiently, reducing the need for complex compensatory mechanisms.

While this specification contains many specific implementation details, these should not be construed as limitations on the scope of what may be claimed, but rather as descriptions of features that may be specific to particular implementations. Certain features that are described in this specification in the context of separate implementations may also be implemented, in combination, in a single implementation. Conversely, various features that are described in the context of a single implementation may also be implemented in multiple implementations, separately, or in any suitable sub-combination. Moreover, although previously described features may be described as acting in certain combinations and even initially claimed as such, one or more features from a claimed combination may, in some cases, be excised from the combination, and the claimed combination may be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional) to achieve desirable results. In certain circumstances, multitasking or parallel processing (or a combination of multitasking and parallel processing) may be advantageous and performed as deemed appropriate. While the various steps in an embodiment method or process are presented and described sequentially, one of ordinary skill in the art will appreciate that some or all of the steps may be executed in different order, may be combined, or omitted, and some or all of the steps may be executed in parallel. The steps may be performed actively or passively. The method or process may be repeated or expanded to support multiple components or multiple users within a field environment. Accordingly, the scope should not be considered limited to the specific arrangement of steps shown in a flowchart or diagram.

Furthermore, any claimed implementation is considered to be applicable to at least a computer-implemented method; a non-transitory, computer-readable medium storing computer-readable instructions to perform the computer-implemented method; and a computer system including a computer memory interoperability coupled with a hardware processor configured to perform the computer-implemented method or the instructions stored on the non-transitory, computer-readable medium.

As used herein, “a CPU”, “controller”, “a processor”, “at least one processor”, or “one or more processors”, generally refers to a single processor configured to perform one or multiple operations or multiple processors configured to collectively perform one or more operations. In the case of multiple processors, the one or more operations could be divided amongst different processors, though one processor may perform multiple operations, and multiple processors could collectively perform a single operation. Similarly, “a memory”, “at least one memory”, or “one or more memories”, generally refers to a single memory configured to store data and/or instructions, multiple memories configured to collectively store data and/or instructions.

As used herein, “gas” and “fluid” may be used interchangeable with either term generally referring to elements, compounds, materials, etc., having the properties of a gas, a fluid, or both a gas and a fluid.

Unless defined otherwise, all technical and scientific terms used have the same meaning as commonly understood by one of ordinary skill in the art to which these systems, apparatuses, methods, processes and compositions belong.

In this disclosure, the terms “top”, “bottom”, “side”, “above”, “below”, “up”, “down”, “upward”, “downward,” “horizontal,” “vertical,” and the like do not refer to absolute directions. Instead, these terms refer to directions relative to a nonspecific plane of reference. This non-specific plane of reference may be vertical, horizontal, or other angular orientation.

The singular forms “a”, “an”, and “the”, include plural referents, unless the context clearly dictates otherwise. Within a claim, reference to an element in the singular is not intended to mean “one and only one” unless specifically so stated, but rather “one or more”. Unless specifically stated otherwise, the term “some”refers to one or more.

Embodiments of the present disclosure may suitably “comprise”, “consist”, or “consist essentially of”, the limiting features disclosed, and may be practiced in the absence of a limiting feature not disclosed. As used here and in the appended claims, the words “comprise”, “has”, and “include”, and all grammatical variations thereof are each intended to have an open, non-limiting meaning that does not exclude additional elements or steps.

“Optional” and “optionally” means that the subsequently described material, event, or circumstance may or may not be present or occur. The description includes instances where the material, event, or circumstance occurs and instances where it does not occur.

“Coupled” and “coupling” means that the subsequently described material is connected to previously described material. The connection may be a direct, or indirect connection, and may, or may not, include intermediary components such as plumbing, wiring, fasteners, mechanical power transmission, electrical communication, wired and/or wireless transmission, etc., which may be suitable to affect operation of the components.

As used, the term “determining” encompasses a wide variety of actions. For example, “determining” may include calculating, computing, processing, deriving, investigating, looking up, for example, looking up in a table, a database, or another data structure, and ascertaining. In addition, “determining” may include receiving, for example, receiving information, and accessing, for example, accessing data in a memory. In addition, “determining”may include resolving, selecting, choosing, and establishing.

When the word “approximately” or “about” are used, this term may mean that there may be a variance in value of up to ±10%, of up to 5%, of up to 2%, of up to 1%, of up to 0.5%, of up to 0.1%, or up to 0.01%.

Ranges may be expressed as from about one particular value to about another particular value, inclusive. When such a range is expressed, it is to be understood that another embodiment is from the one particular value to the other particular value, along with all particular values and combinations thereof within the range.

As used, terms such as “first” and “second” are arbitrarily assigned and are merely intended to differentiate between two or more components of a system, an apparatus, or a composition. It is to be understood that the words “first” and “second” serve no other purpose and are not part of the name or description of the component, nor do they necessarily define a relative location or position of the component. Furthermore, it is to be understood that that the mere use of the term “first” and “second” does not require that there be any “third” component, although that possibility is envisioned under the scope of the various embodiments described.

Although only a few example embodiments have been described in detail, those skilled in the art will readily appreciate that many modifications are possible in the example embodiments without materially departing from the disclosed scope as described. Accordingly, all such modifications are intended to be included within the scope of this disclosure as defined in the following claims. In the claims, means-plus-function clauses are intended to cover the structures described as performing the recited function and not only structural equivalents, but also equivalent structures. It is the express intention of the applicant not to invoke 35 U.S.C. § 112(f), for any limitations of any of the claims, except for those in which the claim expressly uses the words ‘means for’ together with an associated function.

While the foregoing is directed to embodiments of the present disclosure, other and further embodiments of the disclosure may be devised without departing from the basic scope thereof, and the scope thereof is determined by the claims that follow.

What is claimed is:

1. A processing chamber, comprising:
an electrode driven by a power source coupled to a substrate, wherein a first capacitance is produced between the electrode and the substrate;
an edge ring disposed adjacent the substrate, wherein a second capacitance is produced between the electrode and the edge ring; and
at least one balance capacitor disposed within the processing chamber to match the second capacitance to the edge ring to the first capacitance to the substrate.

2. The processing chamber of claim 1, wherein the balance capacitor is a fixed capacitor.

3. The processing chamber of claim 1, wherein the balance capacitor is a variable capacitor.

4. The processing chamber of claim 1, wherein the balance capacitor includes a single capacitor in series with a cooling plate of the processing chamber.

5. The processing chamber of claim 1, wherein the balance capacitor includes a single capacitor in series with the edge ring, the single capacitor coupled to the edge ring via a common conductor line extending to a cooling plate of the processing chamber.

6. The processing chamber of claim 1, wherein the balance capacitor includes a first capacitor in series with the edge ring and a second capacitor in series with a cooling plate of the processing chamber.

7. The processing chamber of claim 1, wherein a third capacitance produced between the substrate and plasma generated over the substrate is configured to be matched with a fourth capacitance produced between the edge ring and the plasma.

8. The processing chamber of claim 7, wherein the third capacitance is matched with the fourth capacitance by making an area of the substrate equal to an area of the edge ring.

9. The processing chamber of claim 8, wherein the power source is a radio-frequency (RF) power source.

10. The processing chamber of claim 8, wherein the power source is a pulsed-voltage technology (PVT)-enabled power source.

11. The processing chamber of claim 1, wherein the balance capacitor includes a first capacitor and a second capacitor in series with a cooling plate of the processing chamber, the first capacitor and the second capacitor coupled to the power source via a common conductor line extending.

12. The processing chamber of claim 1, wherein a sliding ring is disposed adjacent the edge ring to adjust capacitive coupling characteristics resulting from the balance capacitor.

13. The processing chamber of claim 1, wherein the edge ring moves and the balance capacitor is adjusted to create a flat plasma sheath profile over the substrate and the edge ring.

14. A processing chamber, comprising:
an electrode driven by a power source coupled to a substrate, wherein a first capacitance is produced between the electrode and the substrate;
an edge ring disposed adjacent the substrate, wherein a second capacitance is produced between the electrode and the edge ring; and
at least one variable balancing capacitor disposed within a junction box to match the second capacitance to the edge ring to the first capacitance to the substrate.

15. The processing chamber of claim 14, wherein the edge ring is fixed in place and free of coatings.

16. The processing chamber of claim 14, wherein the variable balancing capacitor includes a single variable capacitor in series with the edge ring.

17. The processing chamber of claim 14, wherein the variable balancing capacitor includes a first variable capacitor driven by a first power source and a second variable capacitor driven by a second power source.

18. A processing chamber, comprising:
an electrode driven by a power source coupled to a substrate, wherein a first capacitance is produced between the electrode and the substrate;
an edge ring disposed adjacent the substrate, wherein a second capacitance is produced between the electrode and the edge ring;
at least one capacitor in series with the edge ring to match the second capacitance to the edge ring to the first capacitance to the substrate; and
a sliding ring disposed adjacent the edge ring to adjust capacitive coupling characteristics resulting from the at least one capacitor.

19. The processing chamber of claim 18, wherein a third capacitance produced between the substrate and plasma generated over the substrate is configured to be matched with a fourth capacitance produced between the edge ring and the plasma.

20. The processing chamber of claim 19, wherein the third capacitance is matched with the fourth capacitance by making an area of the substrate equal to an area of the edge ring.
